(19) United States
(12) Patent Application Publication
(10) Pub. No.: US 2025/0309914 A1
(43) Pub. Date: Oct. 2, 2025

(54) METHOD FOR DESIGNING A SIGMA-DELTA CONVERTER

(71) Applicant: Commissariat à l'Energie Atomique et aux Energies Alternatives, PARIS (FR)

(72) Inventors: Arnaud VERDANT, GRENOBLE (FR); William GUICQUERO, GRENOBLE (FR)

(21) Appl. No.: 19/083,545

(22) Filed: Mar. 19, 2025

(30) Foreign Application Priority Data
Mar. 29, 2024 (FR) 2403328

(51) Int. Cl. H03M 3/00

(52) U.S. Cl. CPC H03M 3/39

(57) ABSTRACT

The present description concerns a method for designing a sigma-delta type converter comprising a step of supervised deep learning applied to a converter model. The converter model comprises at least one recurrent encoder and at least one recurrent decoder. Each recurrent encoder is based on a generic model comprising a succession of K identical generic cells Cellk, with K an integer parameter greater than or equal to 1 and k an integer index ranging from 1 to K. The sigma-delta converter is obtained by manufacturing an electronic circuit corresponding to the model obtained after the training.

### FIELD

The present disclosure generally concerns electronic circuits and, more particularly, sigma-delta converters, whether they are analog-to-digital (AD) or analog-to-information (A2I) converters.

### BACKGROUND

In The use of deep learning methods to design analog and mixed-signal circuits has been provided for the design of analog-to-digital or analog-to-information converters.

For example, artificial intelligence (AI)-assisted methods have been used on the outputs of known converters to mitigate material non-idealities of these known converters. However, in this case, AI-assisted methods are not directly used to design the converter.

As another example, converter topologies inspired by neural networks have been provided, sometimes by applying deep learning methods to adapt the weights of these topologies. However, in these other examples, each provided topology is predefined from a specific known converter, and thus cannot be used again to develop a new converter based on, for example, a specification listing the hardware and performance constraints that it would be desirable for this new converter to meet. For example, the article “Design Automation of Analog and Mixed Signal Circuits Using Neural Networks—A Tutorial Brief” by G. Linan-Cembrano et al, published in “IEEE Transactions on Circuits and Systems II: Express Briefs” discloses works on the use of artificial intelligence to assist the porting of a reference topology to the most suitable hardware implementation.

### SUMMARY

There exists a need for a sigma-delta converter design method which overcomes all or part of known converter design methods using deep learning processes and/or artificial intelligence.

An embodiment overcomes all or part of the disadvantages of known sigma-delta type converter design methods.

An embodiment provides a method for designing a sigma-delta type converter comprising a step of supervised deep learning applied to a converter model, wherein:
the converter model comprises at least one recurrent encoder and at least one recurrent decoder;
each recurrent encoder is based on a generic model comprising a succession of K identical generic cells Cellk, with K an integer parameter greater than or equal to 1 and k an integer index ranging from 1 to K;
the converter operates at an oversampling rate of N, with N an integer greater than or equal to 1;
each conversion by the converter comprises N Cycles C[n], with n an integer index ranging from 1 to N;
each cell Cellk of the generic model is a recurrent neural network which, at each cycle C[n], calculates a product of an input vector X[n] by a weight vector Wk of the cell Cellk and delivers an output vector Qk[n] comprising D pairs of outputs Akd[n] and Bkd[n], with:
   D an integer greater than or equal to 1 and d an integer index ranging from 0 to D−1,
   Akd[n] the result of the product calculated by the cell Cellk delayed by d cycles,
   Bkd[n] a quantization of the result of the product calculated by the cell Cellk delayed by d cycles; and
at each beginning of a cycle C[n], vector X[n] is the same for all cells Cellk and comprises, for example is equal to, the concatenation of the K vectors Qk[n] and of a sample x[n], for cycle C[n], of a signal x to be converted,
and wherein the sigma-delta converter is obtained by manufacturing an electronic circuit corresponding to the model obtained after the training.

According to an embodiment, each recurrent encoder models a sigma-delta modulator of the converter, and each recurrent decoder models a filter of the converter.

According to an embodiment, each recurrent decoder is based on one or a plurality of successions of simple recurrent neural networks.

According to an embodiment, at least one constraint determined by a material property or by a functional property of the converter to be manufactured is applied to the converter model, preferably to each encoder.

According to an embodiment, said at least one constraint comprises:
a constraint determined by a maximum output dynamic range of one of the K cells Cellk and corresponding to an addition of a clipping layer at the output of said cell Cellk; and/or
a constraint determined by a robustness to temporal non-idealities and corresponds to the adding on an internal node of the encoder of a data augmentation layer modeling random Gaussian noise; and/or
a constraint determined by a sizing of circuits implementing weights of the encoder and corresponding to a quantization-aware training; and/or
a constraint determined by a surface area of the converter to be manufactured and corresponding to a masking of encoder weights; and/or
a constraint determined by a topology of the converter to be manufactured and corresponding to a masking of encoder weights; and/or
a constraint determined by a surface area of the converter to be manufactured and corresponding to a masking of encoder weights.

According to an embodiment, at least one regularization determined by a material property or by a functional property of the converter is applied to the converter model.

According to an embodiment:
a regularization is determined by a surface area of the converter to be manufactured and corresponds to an L1 regularization applied to the encoder weights; and/or
a regularization is determined by an attenuation of inner signals and corresponds to a penalty when a weight of a loopback path of a cell Cellk is smaller than 1.

According to an embodiment, a cost function used for training comprises a term determined by a regularization function determined by converter saturation conditions.

According to an embodiment, the cost function comprises a term determined by a fidelity function of the type of a logarithm of the sum of the exponentials of the differences.

According to an embodiment, the converter manufacturing comprises an implementation of each non-zero weight of the encoder model trained by a capacitive circuit having a capacitive element, a value of which is determined by said weight.

According to an embodiment, the converter manufacturing comprises an implementation of each non-zero weight of the encoder model trained by a resistive circuit having a resistance, a value of which is determined by said weight.

According to an embodiment, the training is quantization-aware.

According to an embodiment, the decoder is determined by a functionality of the converter to be manufactured.

According to an embodiment, the converter to be manufactured implements a cyclic and alternated sampling of a plurality of input channels of the converter.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows an analog-to-digital converter of sigma-delta type;

FIG. 2 shows an example of a recurrent autoencoder structure modeling the structure of the sigma-delta converter of FIG. 1;

FIG. 3 shows an example of implementation of a portion of the converter of FIG. 2;

FIG. 4 shows another example of implementation of the converter of FIG. 2;

FIG. 5 illustrates an example of embodiment of a generic cell based on a recurrent neural network, for a generic recurrent encoder model;

FIG. 6 illustrates an example of a generic model based on the generic cell of FIG. 5;

FIG. 7 illustrates an update of the outputs of the cells of the model of FIG. 6;

FIG. 8 shows an example of a decoder;

FIG. 9 is a flowchart illustrating an implementation mode of a sigma-delta converter design method;

FIG. 10 illustrates an embodiment of a transposition of a generic cell into a circuit;

FIG. 11 illustrates an embodiment of a transposition of a converter model into a circuit as well as an example of control signals of the circuit;

FIG. 12 illustrates an embodiment of a circuit for a hardware implementation of a converter model;

FIG. 13 illustrates an embodiment of another circuit for a hardware implementation of a converter model;

FIG. 14 illustrates an embodiment of still another circuit for a hardware implementation of a converter model;

FIG. 15 illustrates an embodiment of still another circuit for a hardware implementation of a converter model;

FIG. 16 illustrates an embodiment of a transposition of a converter model into a circuit as well as an example of control signals of the circuit;

FIG. 17 illustrates another example of a decoder;

FIG. 18 illustrates a cyclic, alternated, and interleaved sampling between three input channels of a converter;

FIG. 19 illustrates, in the form of blocks, an example of a converter model adapted to an alternated and interleaved sampling of the input channels of the converter;

FIG. 20 illustrates, in the form of blocks, another example of a converter model adapted to an alternated and interleaved sampling of the input channels of the converter;

FIG. 21 illustrates, the form of blocks, an example of an analog-to-information converter model;

FIG. 22 illustrates results of inference of a latent parameter by the converter model of FIG. 21 after a supervised deep learning;

FIG. 23 illustrates results of inference of a latent parameter by the converter model of FIG. 21 after a supervised deep learning;

FIG. 24 illustrates results of inference of a latent parameter by the converter model of FIG. 21 after a supervised deep learning;

FIG. 25 illustrates results of inference of a latent parameter by the converter model of FIG. 21 after a supervised deep learning; and

FIG. 26 illustrates steps of the method described in relation with FIG. 9.

### DETAILED DESCRIPTION OF THE PRESENT EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

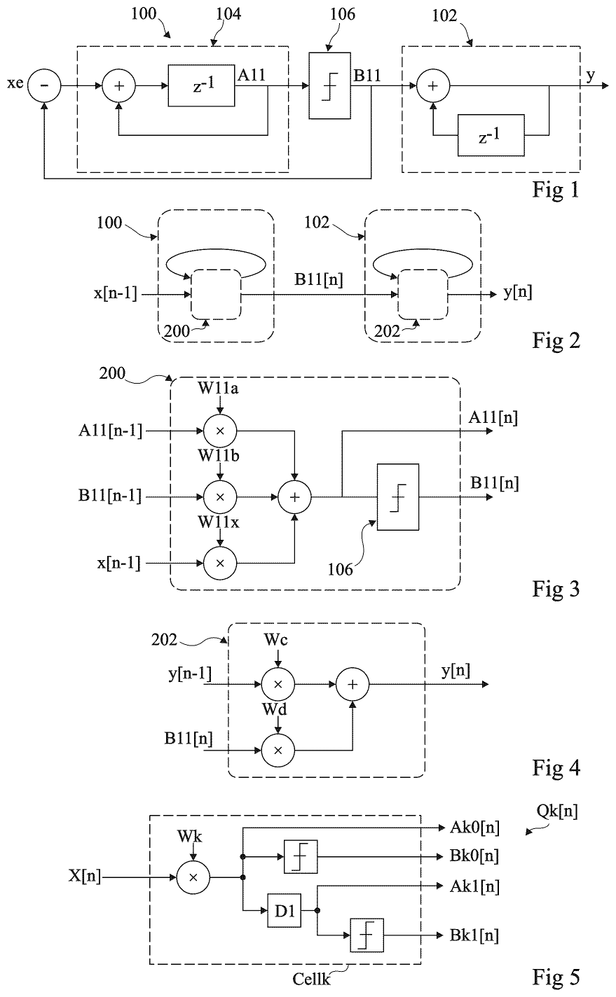

FIG. 1 schematically shows an example of a sigma-delta type analog-to-digital converter of order M, with M an integer greater than or equal to 1 and equal to 1 in the example of FIG. 1. The converter here is a converter which is configured to convert an analog and for example DC (direct current) signal x into a digital signal. The converter is reset at each conversion, each conversion comprising, as will be described in more detail hereafter, N cycles.

The converter comprises a sigma-delta modulator 100 and a filter 102 (each delimited by dotted lines in FIG. 1).

Modulator 100 comprises an analog integrator 104 (delimited by dotted lines in FIG. 1) and a quantizer 106, here over one bit.

Filter 102 is for example implemented by a digital integrator, as shown in FIG. 1.

The converter operates with an oversampling rate N, commonly designated with the acronym OSR, with N an integer greater than or equal to 1, for example greater than or equal to 2. Thus, each conversion of an input signal x comprises N cycles C[n], with n an integer index ranging from 1 to N.

At each cycle C[n], modulator 100 receives a sample xe (or x[n−1]) corresponding to the sampling of signal x at the previous cycle. At each cycle C[n], the converter implements the following three operations:
the difference between the sample xe of the previous cycle and the output B11 of modulator 100 at the previous cycle is integrated by analog integrator 104, to supply the output A11 of integrator 104;
output A11 is quantized by quantizer 106 to update the output B11 of modulator 100;
output B11 is supplied to filter 102, which then calculates the digital output y (or y[n]) of the converter for this cycle n.

In other words, the filter implements the following z-equation:

$$A 11 = {Z}^{- 1} ( A 11 + xe - B 11 ) with {Z}^{- 1} a delay by one cycle . \qquad [ Math 1 ]$$

This is equivalent in time to:

$$A 11 [ n ] = A [ n - 1 ] + x [ n - 1 ] - B 11 [ n - 1 ] \qquad [ Math 2 ]$$

In practice, the inner signals of the converter have to remain within a given dynamic range centered on the threshold of quantizer 106. This is made possible due to the negative feedback loop controlled by the sign of the output signal B11 of the quantizer. As an example, a weighting may be added between the output of the input differentiator and the input of integrator 104.

For the example shown in FIG. 1, this behavior can be expressed according to the above equations [Math 3] and [Math 4], while respecting the [Math 5] hypotheses:

$$A 11 [ n ] = {\sum }_{i = 0}^{n - 1} x [ i ] - {\sum }_{i = 0}^{n - 1} B 11 [ i ] with i an integer index . \qquad [ Math 3 ]$$

$$B 11 [ n ] = \frac{1}{2} * sign ( A 11 [ n ] ) \\ where sign ( A 11 [ n ] ) is the function returning the sign \\ of A 11 [ n ] with respect to the threshold of quantizer 106. \qquad [ Math 4 ]$$

$$\{ \begin{matrix}n \geq 1 \\ \vert x [ i ] \vert \leq \frac{1}{2} \\ B 11 [ i ] ∈ \{ - \frac{1}{2} , \frac{1}{2} \} for i > 0 , and B 11 [ 0 ] = 0\end{matrix} \qquad [ Math 5 ]$$

The digital signal xq obtained at the end of each conversion, that is, at the end of N corresponding conversion cycles, is then equal to y[N] and can then be expressed, in this example, according to equation [Math 6]:

$$xq = y [ N ] = \frac{{\sum }_{n = 1}^{N} B 11 [ n ]}{N} , \\ the 1 / N normalization not being shown in FIG . 1. \qquad [ Math 6 ]$$

In the example of FIG. 1, in integrator 104, the one-cycle delay Z⁻¹ is applied to the feedback path. However, those skilled in the art will be capable of adapting this example to the case where, in integrator 104, the one-cycle delay Z⁻¹ is applied to the feedback path, between output A11 and the adder block, by providing for a one-cycle delay Z⁻¹ to also be applied to the feedback path between output B11 and the subtracting block.

In the example of FIG. 1, in filter 102, the one-cycle delay Z⁻¹ is applied to the feedback path between output y[n] and the adder block. Here again, those skilled in the art will be capable of adapting this example to the case where, in filter 102, the one-cycle delay Z⁻¹ is applied to the direct path, between the adder block and output y[n].

To decrease the quantization noise, it is known to use converters of order M greater than 1. In this case, modulator 104 comprises a succession of integrators, and the filter comprises, for example, a succession of integrators.

The provided method aims at designing a converter, and more particularly, the encoder of the converter, by implementing a supervised deep learning associating input data with output data, based on the exploration of sigma-delta converter topologies. Noting that sigma-delta converters have recursive structures, it is provided to model a sigma-delta type converter by a recursive autoencoder structure such as illustrated in FIG. 2. The recurrent autoencoder then supplies a digitized image of the analog input signal x in the example illustrated in FIG. 2. In other examples, the recurrent autoencoder provides a digital estimate of one or a plurality of latent parameters of the input signal.

FIG. 2 shows an example of a recurrent autoencoder structure modeling the structure of the sigma-delta converter of FIG. 1.

Modulator 100 (delimited by dotted lines in FIG. 2) is here implemented by a recurrent encoder 100. Recurrent encoder 100 comprises, in this example, where M is equal to 1, a cell 200 corresponding to a recurrent neural network (RNN). This cell 200 is configured to implement recursive processings where the output data of the cell, for a given cycle, are updated based on, or according to, the output data of the cell at the previous cycle and to one or a plurality of the input data (or values) of the cell. Recurrent neural networks are well known to those skilled in the art and are not defined again herein. As an example, a recurrent neural network can be mathematically similar to an infinite impulse response filter, due to its recurrence.

Filter 102 is here implemented by a recurrent decoder 102. Recurrent decoder 102 comprises, in this example, a cell 202 corresponding to a simple recurrent neural network (SRNN). For example, a simple recurrent neural network is configured to implement at least the following operation: the output of cell 202, y[n] in the example shown in FIG. 2, corresponds to the sum of the output of cell 202 at the previous cycle, y[n−1] in the example of FIG. 2, weighted by a corresponding weight Wc (not shown in FIG. 2), and of an input of cell 202, B11[n] in the example of FIG. 2, weighted by a corresponding weight Wd (not shown in FIG. 2). This corresponds to a dot product between an input vector and a weight vector where, in this example, the input vector is equal to the concatenation of y[n−1] and of B11[n] and the weight vector is formed of weights Wc and Wd. The cell 202 of FIG. 2 corresponds to the filter 102 of FIG. 1 when weights Wc and Wd are unitary. Simple recurrent neural networks are well known to those skilled in the art and are not defined again herein. For example, the source code of a simple recurrent neural network is available on the following web page:
https://github.com/keras-team/keras/blob/v2.14.0/keras/layers/rnn/simple_rnn.py#L193-L214.

FIG. 3 shows an example of implementation of a cell 200 corresponding to the sigma-delta converter of order M=1 of FIG. 2.

Cell 200 comprises a recurrent neuron layer, or in other words, corresponds to a recurrent neural network. The cell or neuron layer 200 is said to be recurrent in that it receives its outputs A11 and B11 on its inputs, and more particularly in that it receives, at a cycle C[n] of given index n, the outputs A11[n−1] and B11[n−1] of the previous cycle C[n−1] (the one-cycle delay Z⁻¹ not being shown in FIG. 3).

At each cycle C[n], cell 200 also receives the sample x[n−1] corresponding to this cycle.

Cell 200 is configured to multiply each of its inputs A11[n−1], B11[n−1], and x[n−1] by a corresponding weight W11a, W11b, and W11x respectively, and to add up the results of these products. The result of the addition corresponds to output A11[n], and the quantization of output A11[n] by quantizer 106, which actually corresponds to an activation layer, results in output B11[n]. In the example of FIG. 3, quantizer 106 is a two-level quantizer. However, those skilled in the art will be capable of adapting this example to the case where quantizer 106 quantizes on more than two levels. For example, quantizer 106 may be a 4-level quantizer and output B11[n] can then take 4 quantized values, preferably evenly distributed, for example between −0.5 and 0.5 in the conditions of the example of equation [Math 4] where B11 belongs to the range −0.5; 0.5. Due to the fact that the recurrent cell or neuron layer 200 delivers a quantized output B11, this recurrent cell or neuron layer 200 is, for example, said to have a quantized output.

In other words, cell 200 is configured to calculate the dot product of its input vector X[n]=[x[n−1], A11[n−1], B11[n−1]] by its weight vector W11=[W11x, W11a, W11b], to deliver output A11[n] equal to the result of this dot product, and to deliver output B11[n] corresponding to the one-bit quantization of output A11[n]. Cell 200 thus delivers an output vector Q1[n]=[A11[n], B11[n]].

The modulator 100 shown in FIG. 1 is obtained with cell 200 when weights W11x, W11a, and W11b are respectively equal to 1, 1, and −1.

In the example of FIG. 3, the one-cycle delays Z⁻¹ are not shown. In this example, a one-cycle delay is arranged on the feedback path coupling output A11[n] to input A11[n−1] of cell 200, and a one-cycle delay is arranged on the feedback path coupling output B11[n] to input B11[n−1]. However, those skilled in the art will be capable of adapting this example to the case where the feedback paths of data A11 and B11 are devoid of delay, and where a one-cycle delay is provided between the adder block of cell 200 and output A11[n], as shown in the example of FIG. 1.

FIG. 4 shows an example of implementation of a simple neural network 202 corresponding to the example of filter 102 of the sigma-delta converter of order M=1 of FIG. 2. Neural network 202 is said to be simple in that it comprises a single recurrent neuron layer.

Neural network 202, that is, its neuron layer, is recurrent in that it takes as an input, at a given cycle C[n] of given index n, the output y[n−1] that network 202 has delivered at the previous cycle C[n−1]. Further, at a cycle C[n] of given index n, network 202 also takes as an input the output B11[n] of cell 200. In this example, network 202 multiplies each of its inputs y[n−1] and B11[n] by the corresponding weights Wc and Wd respectively, and the output y[n] of the network is then equal to the sum of these products. By setting Wc=1 and Wd=1/N, it is returned to the example of filter 102 of FIG. 1 (in which the 1/N normalization is not shown). A normalization depending on index n could also be introduced, so as to obtain a normalized output y[n] for each index n by using the following recurrence relation:

$$y [ n ] = \frac{B 11 [ n ] + ( n - 1 ) y [ n - 1 ]}{n} \qquad [ Math 7 ]$$

In the example of FIG. 4, the one-cycle delay Z⁻¹ is not shown. In this example, this one-cycle delay is arranged on the feedback path coupling the output y[n] to the input y[n−1] of cell 202. However, those skilled in the art will be capable of adapting this example to the case where the feedback path of data item y is delay-free, and where this one-cycle delay is provided between the adder block of the cell and the output y[n] of the cell.

The above-described drawings show that a specific sigma-delta converter topology can be modeled by an autoencoder comprising a recursive encoder 100 implemented based on a recurrent neural network cell 200, and a recursive decoder 102 implemented based on a simple recurrent neural network.

As an example, the above-described autoencoder could undergo a step of supervised deep learning, for example to obtain values for weights W11a, W11b, W11x, Wy, and Wb, although this would be of little interest for a sigma-delta converter of order 1. However, this could be of interest for sigma-delta converters of order greater than 1, on the condition of modeling each of these converters with a model based on recurrent neural networks.

However, there exist many different topologies for sigma-delta converters. These topologies are, for example, determined by:
the nature of the input signal; and/or
the type of information that the converter needs to output;
the required performance that the converter needs to have in terms of conversion accuracy; and/or
the maximum surface area that the converter needs to have; and/or
the order M of the converter; and/or
the value N of the oversampling rate; and/or
a desired robustness to noise; and/or
maximum excursions that the converter stage output signals need to have; and/or
constraints on converter weights, this list being non-exhaustive.

To improve the operation of a given sigma-delta type converter having a specific topology, it could first be considered to form from this specific topology a specific model of this topology, this model comprising an encoder-decoder pair with an encoder model (corresponding to the modulator) based on recurrent neural networks and a decoder model (corresponding to the filter) also based on recurrent neural networks, for example, simple recurrent neural networks. Once this formalism has been set, a supervised deep learning could then be implemented on the model extracted from this specific topology. However, the design of such a model needs to be adapted to each topology of the considered sigma-delta type converter, which may be complex and tedious. Further, this design work for a model based on recurrent neural networks would then have to be done for each different sigma-delta type converter topology, which is not desirable due to the large number of different sigma-delta type converter topologies.

There is here provided a method for designing a sigma-delta type converter in which a generic converter model is used, and a supervised deep learning is applied to this generic model to obtain a sized converter model which is then manufactured. Indeed, the aim of the present disclosure is not to train a neural network to then program a processor dedicated to the implementation of neural networks, but rather to obtain a specific circuit, for example an integrated circuit, meeting a set of specifications, or criteria, linked to the targeted hardware implementation. In other words, rather than providing a method for sizing a specific sigma-delta type converter topology by sequentially ensuring that it satisfies a set of specifications linked to a targeted hardware implementation, a generic sigma-delta converter topology model is here provided. The sizing of this model is optimized, during a deep learning implemented on the model, to jointly satisfy a set of hardware specifications. Indeed, these hardware specifications are transcribed in the form of constraints and/or regularizations on the weights and the data of the model, so as to limit the search space during the supervised deep learning and to guide the learning (or optimization) process towards a topology meeting the expected specifications. The converter thus obtained is, for example, designated by the acronym RCN (Recurrent Converter Network).

Still in other words, there is here provided a generic topology having very large degrees of freedom in terms of possible interconnections between internal cells, with no imprint of any particular topology. This generic topology enables to cover a multitude of configurations, with no preconceived ideas about the final configuration retained. The deep learning will enable to assign a specific weight to each of the interconnects, so as to converge on a final topology adapted to the training data. The starting point thus is a generic (or general) topology having a random weighting of the various possible interconnects (and thus agnostic of the addressed problem), which will be specialized by learning, or with a weighting corresponding to a reference structure which will be desired to evolve.

More specifically, this generic model, which corresponds to an autoencoder, comprises a recurrent encoder corresponding to the sigma-delta modulator of the generic model, and a recurrent decoder corresponding to the filter of the generic model. Both encoder and decoder correspond to layers of recurrent neural networks (RNN).

More particularly still, the provided converter model is said to be generic because the modeling of its encoder is based on a cascade (or succession) of K identical generic cells, with K an integer greater than or equal to 1, preferably greater than or equal to 2, where each generic cell corresponds to a recurrent neural network. Number K then is a parameter (or hyper-parameter) of the generic model. Number K is, for example, determined by the targeted order M of the converter, and is, for example, equal to M+1.

FIG. 5 illustrates an example of embodiment of a generic cell Cellk, k being an integer index ranging from 1 to K and identifying the cell Cellk among the succession of K cells Cellk of the recurrent encoder.

At each cycle C[n], cell Cellk receives an input vector X[n]. This vector X[n] is updated at each beginning of a cycle C[n], from the output data of the K cells Cellk obtained at the end of the previous cycle C[n−1]. Although a single cell Cellk is shown, when the generic model comprises a plurality of successive cells Cellk, these cells receive the same vector X[n], which is identical for all cells Cellk at the beginning of each cycle C[n].

Cell Cellk comprises a weight layer (or vector) Wk, comprising as many weights as there are elements in the input vector X[n] of cell Cellk.

Cell Cellk is configured, at each cycle C[n], to multiply each of its inputs by a corresponding weight, to provide the sum Ak0[n] of these products, and the quantization Bk0[n] of this sum. In other words, cell Cellk is configured, at each cycle, to perform the dot product of its input vector X[n] by its weight vector Wk, the result of this dot product being the cell output Ak0[n], and the quantization of output Ak0[n] providing output Bk0[n].

Preferably, to enable to obtain a generic model allowing greater freedom of choice during the supervised deep learning step, cell Cellk is configured to also provide outputs corresponding to outputs Ak0[n] and Bk0[n], but with a delay of at least one conversion cycle. In the example of FIG. 5, cell Cellk provides outputs Ak1[n] and Bk1[n] corresponding to the respective outputs Ak0[n] and Bk0[n] delayed by one cycle, as represented by a block D1 in FIG. 5.

More generally, the generic cell Cellk is thus configured to provide, at each cycle C[n], D pairs of outputs Akd[n], Bkd[n], with Akd[n] the result of the product of input vector X[n−d] by weight vector Wk, and Bkd[n] the quantization of the result of the product of input vector X[n−d] by weight vector Wk, D being an integer greater than or equal to 1, preferably 2, and d being an integer index ranging from 0 to D−1.

Thus, for a cycle C[n] of given index n, output Ak0[n] corresponds to the dot product X[n]·Wk (also noted <X[n],Wk>) calculated by cell Cellk at this cycle C[n], with output Bk0[n] corresponding to the quantization of output Ak0[n].

Further, for this same cycle C[n], output Akd[n] corresponds to the dot product X[n−d]. Wk, and output Bkd[n] corresponds to the quantization of output Akd[n]. In other words, at the beginning of each conversion cycle C[n], Akd[n]=Ak0[n−d] and Bkd[n]=Bk0[n−d]. Still in other words, at the beginning of each conversion cycle C[n], output Akd[n] corresponds to the output Ak0[n] calculated by cell Cellk d cycles before cycle C[n] and output Bkd[n] corresponds to the output Bk0[n] calculated by cell Cellk d cycles before cycle C[n]. Still in other words, at each beginning of a cycle C[n], Akd[n]←Akd−1[n−1] and Bkd[n]←Bkd−1[n−1], with “←” a mathematical operator meaning “receives”.

In the example of FIG. 5, and in the rest of the disclosure, D is, as an example, selected to be equal to 2, and cell Cellk then delivers, at each cycle C[n], a pair of non-delayed outputs Ak0[n], Bk0[n], and a pair of outputs Ak1[n], Bk1[n] delayed by one cycle. In FIG. 5, for each non-zero value of d, a block Dd represents the application of a delay of d cycles between the pair of non-delayed outputs Ak0[n], Bk0[n] and a pair of outputs Akd[n], Bkd[n] delayed by d cycles. In the example of FIG. 5, cell Cellk comprises a block D1.

It should be noted that integer D is a parameter (or hyper-parameter) of the provided generic model.

At each cycle C[n], the set of D pairs of outputs Akd[n], Bkd[n] forms the output vector Qk[n] of cell Cellk.

At each cycle C[n], the input vector X[n] of each of the K cells Cellk is then the same for all cells, at least at the beginning of cycle C[n] before cells Cellk calculate their outputs Ak0[n] and Bk0[n], which are thus updated during cycle C[n]. Vector X[n] is equal to the concatenation of sample x[n] at the beginning of cycle C[n] and of the K output vectors Qk[n] of the K cells Cellk which are updated during the cycle based on sample x[n]. Vector X[n] thus comprises 1+K·2·D elements (or inputs for cells Cellk), just as the vector Wk of each cell Cellk comprises 1+K·2·D elements (or weights of cell Cellk). At each cycle C[n], values Ak0[n] and Bk0[n] are updated during cycle C[n] based on the value of x[n] at the beginning of the cycle.

Thus, for each cell Cellk of index k equal to p, with p an integer index ranging from 1 to K, the vector Wp of the weights of cell Cellp, that is, the vector Wk of the weights of the cell Cellk of index k equal to the considered index p, comprises:
a weight Wpx applied to the input x[n] of cell Cellp; and
K times D pairs of weights Wapkd, Wbpkd, with p the integer index of the considered cell Cellp and k ranging from 1 to K.

In each cell Cellk of index k equal to p, or, in other words, in each cell Cellp, for k ranging from 1 to K and for d ranging from 0 to D−1, the weight Wapkd of cell Cellp is applied to the output Akd[n] of cell Cellk, this output Akd[n] of cell Cellk being an input of cell Cellp, and weight Wbpkd is applied to the output Bkd[n] of cell Cellk, this output Bkd[n] of cell Cellk being an input of cell Cellp.

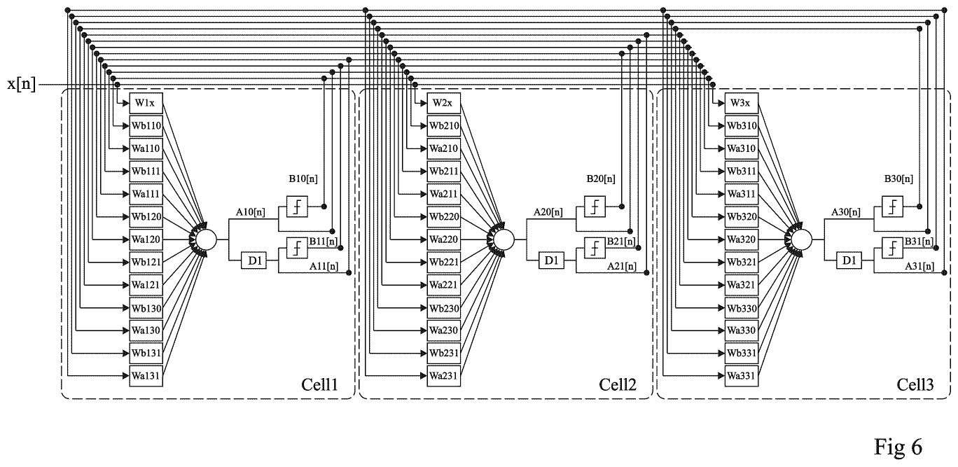

FIG. 6 illustrates by an example the above-described formalism.

FIG. 6 shows an example of an encoder 200 based on a generic model with K=3 successive cells Cellk, in the case where D is equal to 2.

Cells Cellk (Cell1, Cell2, and Cell3 in the example of FIG. 6) are connected one after the other in ascending order of index k. In other words, at each of the N cycles of a conversion, the cells Cellk update their outputs Ak0[n] and Bk0[n] one after the other in ascending order of index k, or, in other words, update their non-delayed outputs sequentially in ascending order of index k. Each update of outputs Ak0[n] and Bk0[n] by a corresponding cell Cellk takes place during part of the corresponding cycle C[n], this part of cycle C[n] being, for example, called intra-cycle, for example intra-cycle of index k. Once a cell Cellk has updated its non-delayed outputs during the intra-cycle of index k, the next cell Cellk+1 updates its non-delayed outputs during the next intra-cycle of index k+1. Once all cells Cellk have updated their non-delayed outputs, the delayed outputs of cells Cellk are updated at the end of cycle C[n], and the next cycle C[n+1] can begin.

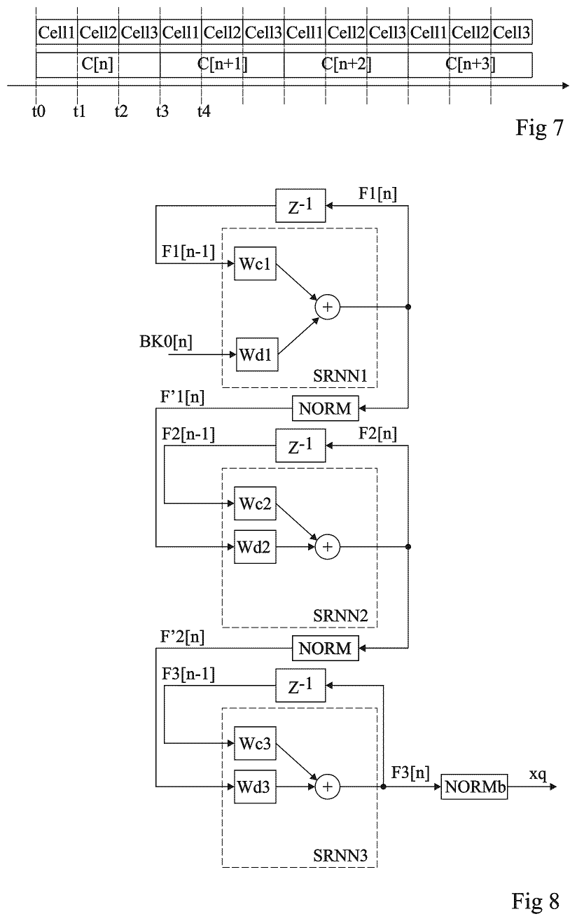

FIG. 7 illustrates the sequential updating of the non-delayed outputs of cells Cellk and, more specifically in this example, the updating of the outputs of cells Cellk in the case where K is equal to 3.

At a time t0, the nth conversion cycle C[n] begins.

From time t0 to the next time t1, still in cycle C[n], cell Cell1 calculates product X[n]. W1, and, at time t1, the new outputs A10[n] and B10[n] of cell Cell1 are available. Outputs A10[n] and B10[n] are thus updated at time t1, and remain unchanged until the end of cycle C[n].

From time t1 to a next time t2, still in cycle C[n], cell Cell2 calculates the product X[n]. W2, and, at time t2, the outputs A20[n] and B20[n] of cell Cell2 are available. Outputs A20[n] and B20[n] are thus updated at time t2, and remain unchanged until the end of cycle C[n].

From time t2 to the next time t3, still in cycle C[n], cell Cell3 calculates the product X[n]·W3, and, at time t3, the outputs A30[n] and B30[n] of cell Cell2 are available. Outputs A30[n] and B30[n] are thus updated at time t3, and remain unchanged until the end of cycle C[n].

Time t3 marks the end of cycle C[n] and the beginning of the next cycle C[n+1]. Thus, at time t3, for each cell Cellk, the delayed outputs of the cells are updated, or, in other words, at each beginning of a cycle C[n+1], Akd[n+1]=Akd−1[n], and Bkd[n+1]=Bkd−1[n]. For example, at time t0, the delayed output A11[n] of cell Cell1 is updated with the value of output A10[n−1] calculated by cell Cell1 at the previous cycle C[n−1]. In other words, at the beginning of each cycle C[n+1], that is, at each end of a cycle C[n], Akd[n+1]←Akd−1[n] and Bkd[n+1]←Bkd−1[n], with “+” a mathematical operator meaning “receives”. The data Akd[n+1], Bkd[n+1] available at each beginning of a cycle C[n+1] are, for example, the inter-cycle data. The inter-cycle data are available at each transition from one cycle C[n] to the next cycle C[n+1], for example at times to and t3 in FIG. 7.

Then, the operation described for cycle C[n] is repeated at cycle C[n+1]. For example, between time t3 and a time t4, cell Cell1 calculates the product X[n+1]·W1, and, at time t4, the outputs A10[n+1] and B10[n+1] of cell Cell1 are available, and so on.

Returning to the example of FIG. 6, the updates of the non-delayed outputs Ak0[n], Bk0[n] of the cells Cellk thus take place from left to right during each cycle C[n]. Thus, in this example, during a given cycle C[n], the outputs A10[n] and B10[n] of cell Cell1 are updated before the outputs A20[n] and B20[n] of cell Cell2, these two outputs themselves being updated before the outputs A30[n] and B30[n] of cell Cell3. This updating of outputs Ak0[n] and Bk0[n] during cycle C[n] is referred to as intra-cycle updating. Intra-cycle updating differs from the updating of outputs Akd[n] and Bkd[n], where d is positive, which is done based on outputs Ak0[n] and Bk0[n] between two successive cycles and which is called, for example, inter-cycle updating, or transfer. For example, in each cycle C[n], the output data updated at each intra-cycle of this cycle C[n] form the intra-cycle data of cycle C[n]. For example, in FIG. 7, the intra-cycle data of cycle C[n] are available at times t1, t2, t3.

In the example of FIG. 6, the vector W1 of the weights of Cell1 is made up of the following K*2*D+1=13 weights:
W1x, Wb110, Wa110, Wb111, Wa111, Wb120, Wa120, Wb121, Wa121, Wb130, Wa130, Wb131, Wa131, the vector W2 of the weights of Cell2 is made up of the following K·2·D+1=13 weights:
W2x, Wb210, Wa210, Wb211, Wa211, Wb220, Wa220, Wb221, Wa221, Wb230, Wa230, Wb231, Wa231, and the vector W3 of the weights of Cell3 is made up of the following K·2·D+1=13 weights:
W3x, Wb310, Wa310, Wb311, Wa311, Wb320, Wa320, Wb321, Wa321, Wb330, Wa330, Wb331, Wa331.

Thus, the weight matrix WM of the example of generic encoder model of FIG. 6 can be written as:

$${WM}^{T} = {( W 1 ; W 2 ; W 3 )}^{T} = ( \begin{matrix}W 1 x & W 2 x & W 3 x \\ W b 110 & W b 210 & W b 310 \\ Wa 110 & Wa 210 & Wa 310 \\ W b 111 & W b 211 & W b 311 \\ Wa 111 & Wa 211 & Wa 311 \\ W b 120 & W b 220 & W b 320 \\ Wa 120 & Wa 220 & Wa 320 \\ W b 121 & W b 221 & W b 321 \\ Wa 121 & Wa 221 & Wa 321 \\ W b 130 & W b 230 & W b 330 \\ Wa 130 & Wa 230 & Wa 330 \\ W b 131 & W b 231 & W b 331 \\ Wa 131 & Wa 231 & Wa 231\end{matrix} ) \\ with T the transposed matrix operator . \qquad [ Math 8 ]$$

The provided generic model allows a greater number of degrees of freedom in the hardware implementation than the model in the example of FIGS. 3 and 4, which is very specific to the converter example of FIG. 1.

Indeed, the provided generic encoder model enables to explore a large diversity of possible topologies, in which each cell Cellk has access, on its inputs, to the outputs of each of the K cells Cellk of the model. For example, the provided generic encoder model enables to explore by supervised deep learning technical solutions, that is, topologies, which would be difficult or impossible to size with conventional analytical approaches. This also enables to provide original topologies jointly using the quantized data at the output of the various cells. Topologies of MASH (Multi-Stage Noise Shaping) type have been provided in literature, where the quantization error is transferred at each cycle from an upstream modulator to a downstream modulator. The provided approach enables to go beyond this MASH technique by transferring from one cell to another, or from one group of cells to another, any possible signal configuration.

FIG. 8 shows an example of a filter 102 that can be used in a generic sigma-delta type converter model based on an encoder with K cells Cellk.

In this example, the considered sigma-delta type converter is configured to convert a DC analog (that is, non-discretized) signal x into a digital signal, and is reset at each conversion, each conversion comprising N cycles C[n].

For such a converter, filter 102 is then formed, for example, of a succession of Q cells SRNNq, each corresponding to a simple recurrent neural network SRNNq of the type described in relation with FIG. 4, with q an integer index ranging from 1 to Q, and Q an integer number. As an example, Q is at least equal, and preferably equal, to the number K of cells Cellk in the encoder. In this example, Q is equal to 3 and filter 102 is sized for a converter comprising, for example, K=3 cells Cellk. Thus, in this example, filter 102 comprises Q equals 3 successive cells SRNN1, SRNN2, and SRNN3.

Networks SRNNq are connected one after the other in ascending order of index q. Each network SRNNq provides one output Fq[n] for each cycle C[n].

In this example, each network SRNNq comprises a first input, a second input, and an output. The first input of each network SRNNq is coupled to the output of this network SRNNq, the second input of the first network SRNN1 being coupled to an output of the encoder, and the second input of each next network SRNNq is coupled to the output of the previous network SRNNq−1.

For example, at each cycle C[n], each network SRNNq receives its output Fq delayed by one cycle (block Z⁻¹ in FIG. 8), that is, its output Fq[n−1] of the previous cycle C[n−1], on its first input.

In this example, the second input of the first network SRNN1 receives a quantized data stream supplied by the cell Cellk of index k equal to K, for example the quantized data stream BK0 supplied by the last cell Cellk in the succession of K cells Cellk of the encoder. As another example, the second input of the first network SRNN1 receives a stream of quantized data delayed by d cycles supplied by cell Cellk, for example the stream of quantized data delayed by d=1 cycle BK1. In this example, the second input of the first network SRNN1 thus receives quantized data stream B30. More specifically, in this example, at each cycle C[n], the second input of the first network SRNN1 receives the output B30[n] of cell Cell3.

For q greater than or equal to 2, that is, for networks SRNNq other than the first network SRNN1, the second input of each network SRNNq is coupled to the output of the previous network SRNNq−1. Although this is not the case in this example, in other examples not shown, one or a plurality of networks SRNNq may comprise, in addition to its second input coupled to the output of the previous network SRNNq−1, a third input coupled to the output of a previous network SRNNq−g, with g an integer index greater than or equal to 2. Further, although this is not the case in the example of FIG. 8, each network SRNNq of index q greater than 1 may have an additional input receiving, like network SRNN1, data item BK0[n].

In this example, for q greater than or equal to 2, the second input of each network SRNNq is coupled to the output Fq−1 of the previous network SRNNq−1 by a normalization stage NORM present on the output of stage SRNNq−1. In other words, for q smaller than 3, the output of each network SRNNq is coupled to the second input of the next network SRNNq+1 by a normalization stage NORM. The aim of these stages NORM is to facilitate deep learning. These stages NORM are not necessarily hardware-equivalent. These stages NORM are optional. Thus, for q greater than or equal to 2, the second input of each network SRNNq receives a data item Fq−1′ corresponding to the normalization by a stage NORM of the output Fq−1 of the previous stage SRNNq−1. For example, at each cycle C[n], for q greater than or equal to 2, the second input of each network SRNNq receives a data item Fq−1′[n].

For example, each stage NORM scales the output Fq−1 of the previous stage SRNNq−1 to provide a normalized output Fq−1′ for a sequence of N successive cycles. As an example, each normalization stage NORM is configured so that, for each of the N cycles of a conversion, the output of stage NORM does not exceed a given maximum value, for example 1. For example, for each cycle C[n], each stage NORM applies a gain to the data item that it receives to deliver its output data item, where this gain may depend on the index n of the considered cycle.

In another example, the normalization stages NORM between networks SRNNq are omitted, and the second input of each network SRNNq having an index q greater than or equal to 2 directly receives the output Fq−1 of the previous network SRNNq−1.

The filter further comprises a normalization stage NORMb configured to receive the output Fq of the last network SRNNq, that is, output F3 in this example, and to deliver signal xq.

Normalization stage NORMb is configured to scale the output value xq of the filter to the same scale as the input signal x of the converter, so as to enable signal x to be reconstructed at each conversion cycle C[n]. Signal xq then corresponds to the output of stage NORMb. As a variant, these normalization stages may also integrate a bias, to execute an affine function of the type: F′x[n]=a·Fx[n]+b, where a and b respectively are the gain and offset of function NORMb.

At each cycle C[n], each network SRNNq is configured to calculate the dot product between its input vector and a corresponding weight vector, and to update its output with the result of this dot product. In particular, for each network SRNNq, the input vector of the network at cycle C[n] comprises the output Fq[n−1] delivered by this same network at the previous cycle C[n−1], as well as the output of network SRNNq−1.

In this example where each network SRNNq comprises two inputs and one output, each network SRNNq comprises a weight vector having a first weight Wcq applied to the first input of the considered network SRNNq, and a second weight Wdq applied to the second input of the considered network SRNNq.

For example, at each cycle C[n]:
the output F1[n] of network SRNN1 corresponds to the sum of its input F1[n−1] multiplied by a weight Wc1 and of its input B30[n] multiplied by a weight Wd1;
the output F2[n] of network SRNN2 corresponds to the sum of its input F2[n−1] multiplied by a weight Wc2 and of its input F′1[n] multiplied by a weight Wd2; and
the output F3[n] of network SRNN3 corresponds to the sum of its input F3[n−1] multiplied by a weight Wc3 and of its input F′2[n] multiplied by a weight Wd3.

An example of a filter adapted to a sigma-delta type converter configured to convert, in N cycles, a DC analog signal x into a digital signal xq has been described hereabove, this converter being reset at each beginning of a conversion.

According to an embodiment, whatever the considered sigma-delta type converter, the filter of the converter is implemented based on one or a plurality of cascades (or successions) of simple recurrent neural networks, or cells, with or without a normalization stage NORM at the output of one or a plurality of these networks.

The previously-described drawings illustrate a sigma-delta type converter model formed of an encoder based on a generic model implemented by K generic cells Cellk of recurrent neural networks, and of a decoder implemented from a plurality of simple recurrent neural networks, also called cells.

It is then possible to implement a supervised deep learning on this converter model.

Although an example of a sigma-delta type converter model, in which the encoder is obtained from a generic model where K is equal to 3, and in which the decoder is of the type described in relation with FIG. 8, has been described hereabove, many other models of sigma-delta type converters can be obtained from the generic cell Cellk, for example by changing value K and/or value D and/or the filter model used for the model.

Usually, supervised deep learning is implemented by means of a set of training data, by defining a cost function Fcost which is desired to be minimized during the supervised deep learning with the training data. More particularly, the values of the encoder and decoder weights are optimized during the deep learning to minimize the cost function.

Function Fcost comprises a fidelity function, or term, Ffid, which expresses, for each training data item input to the model, and thus to the converter, an image of the error between the output value(s) of the model and the expected (ideal) output value(s) for this input.

As an example, in the case of a sigma-delta converter configured to convert a DC analog signal of value xa into a corresponding digital signal xq, reset at each conversion over N cycles, the fidelity function compares, for each training data item, the deviation between the value xa of the signal x input to the model and the value of the digital counterpart xq obtained for this value xa of input signal x.

However, those skilled in the art will be capable of adapting the examples indicated hereafter of a cost function, and in particular the examples of a fidelity function, to the case of a sigma-delta type converter reset at each conversion and having a function other than the conversion of a DC analog signal into a digital signal, for example to a sigma-delta type converter configured to extract one or a plurality of latent parameters from a converter input. In other words, those skilled in the art will be capable of adapting these examples of a cost function, and in particular the examples of a fidelity function, to the case where what is minimized is the error between a latent parameter extracted by the converter from a training data item input to the converter, and the expected latent parameter corresponding to this training data item.

As an example, for each training batch of dimension S, that is, a batch comprises, in this example, S input values xa, with S a positive integer, the function Ffid (xa, xq) of the batch may be based on the mean square error Frmse (xa, xq) between the S pairs of values xa[s] and xq[s] of the batch, with s an integer index ranging from 1 to S:

$$Frmse ( xa , xq ) = \sqrt{\frac{1}{S} {\sum }_{s = 1}^{S} {( xa [ s ] - xq [ s ] )}^{2}} \qquad [ Math 9 ]$$

As another example, the function Fid(xa, xq) of each training batch may be based on a function Flse which is a logarithm of the sum of the exponentials of the differences between the S values xa[s] and xq[s] in the batch:

$$Flse ( xa , xq ) = log ( \frac{1}{S} {\sum }_{s = 1}^{S} {e}^{( \vert xa [ s ] - xq [ s ] \vert )} ) \qquad [ Math 10 ]$$

As another example, the function Fid(xa, xq) of each training batch may be based on a linear combination Fmix(xa, xq) of functions Frmse and Flse:

$$Fmix ( xa , xq ) = A * Frmse ( xa , xq ) + B * Flse ( sa , xq ) , \qquad [ Math 11 ]$$

where A and B are positive factors having a sum equal to 1, for example equal to 0.8 and 0.2 respectively, although those skilled in the art will be capable of predicting other values.

As another example, the function Fid(xa, xq) of each training batch may be based on a linear combination Fmax(xa, xq) of the maximum error between the values xa[s] and xq[s] of the batch and the norm Lp of the error between the values xa[s] and xq[s] of the batch:

$$Fmax ( xa , xq ) = C 1 * {max}_{s} \{ \vert xa [ s ] - xq [ s ] \vert \} + C 2 * {( \frac{1}{S} * {\sum }_{s = 1}^{S} {\vert xa [ s ] - xq [ s ] \vert}^{p} )}^{\frac{1}{p}} \qquad [ Math 12 ]$$

$$With$$

$$\{ \begin{matrix}\frac{c 1 * {max}_{S} \{ \vert xa [ s ] - xq [ s ] \vert \}}{c 2 * {( \frac{1}{S} * {\sum }_{s = 1}^{S} {\vert xa [ s ] - xq [ s ] \vert}^{p} )}^{\frac{1}{p}}} = 0 , 5 , \\ C 1 + C 2 = 1\end{matrix} \qquad [ Math 13 ]$$

where p is the index of norm LP, for example p is equal to 5 for norm LS, and where maxₛ{|xa[s]−xq[s] |} is the function returning the maximum error, in absolute value, of conversion for the considered training batch comprising S pairs of an input value xa[s] and of an output value (or converted value) xq[s], it being understood that in this example of a sigma-delta type converter, the expected output value for a given input value xa[s] is equal to this input value.

Although four examples of fidelity functions Ffid (xa, xq) have been described hereabove, those skilled in the art are capable of providing other fidelity functions adapted to a sigma-delta converter model configured to convert a DC analog signal x of value xa into a digital signal xq, where the converter is reset at each conversion over N cycles. More generally, those skilled in the art are capable of providing fidelity functions adapted to sigma-delta type converter models which are reset at each conversion over N cycles but which have the purpose of extracting one or a plurality of latent parameters from an input supplied to the converter. As an example, these fidelity functions may be adapted in such a way as to optimize various metrics (maximum error, average error, outlier clearance, etc.).

In the examples of fidelity functions Ffid (xa, xq) described hereabove, for each input data item of index s of a given training batch, the error calculated between input xa[s] and its digital counterpart xq[s] is calculated only at the end of the conversion, that is, at the cycle of index N. However, those skilled in the art will be capable of adapting these examples of fidelity functions to the case where, for each input data item of index s of a given batch, the image of the error is calculated, in the case of simple regression, as a sum, for example weighted, of the errors calculated at each of the N conversion cycles between the input data item and its digital counterpart. Such a weighting enables, for example, to take account of the error decrease with the increase of index n during the N conversion cycles, and, for example, also to maximize the converter performance for each conversion cycle.

Usually, function Fcost may, in addition to being based on a fidelity function Ffid, be based on or comprise one or a plurality of regularization functions. These regularization functions are, for example, applied to layers of the model or implemented in the model in the form of a specific layer which does not necessarily have a hardware counterpart. Usually, a regularization is applied to weights or data of the model and aims at guiding the supervised deep learning, for example by expressing a target result (that is, a target specification), for example in the hardware implementation that will be made of the converter based on the trained model.

Thus, according to an embodiment, function Fcost comprises at least one regularization function.

According to an embodiment, said at least one regularization function is determined by a functional property and/or a material property of the converter to be obtained after the supervised deep learning.

According to an embodiment, one of these regularizations aims at ensuring that the excursions of the inner signal of the modulator are limited, which enables to avoid saturations in the hardware converter that will be manufactured from the trained model.

According to an embodiment, a regularization function aims at keeping, for each training batch, and for each of the S training data in the batch, the output signals Ak0 of the K cells Cellk of the encoder within K ranges of respective values ranging from −Δk to +Δk, with Δk a positive threshold value determined, for example, by the value of the power supply voltage to be received by the converter. By defining, for each training batch, Ak0[s] as the maximum value taken during the N cycles of a conversion by signal Ak0 for an input data xa of rank s of the considered training batch, this regularization function Fdr(Ak0) may, for example, be written, for each training batch, as:

$$Fdr ( Ak 0 ) = \sqrt{\frac{1}{K} {\sum }_{s = 1}^{S} {\sum }_{k = 1}^{K} {( Ak 0 [ s ] - clip ( Ak 0 [ s ] , - Δ k , Δ k ) )}^{2}} \qquad [ Math 14 ]$$

$$with$$

$$clip ( Ak 0 [ s ] , - Δ k , Δ k )$$

the function which forces value Ak0[s] to value −Δk when Ak0[s] is smaller than −Δk, and to +Δk when value Ak0[s] is greater than +Δk. As an example, in the rest of the disclosure, Δk is equal to 0.4 in this example where the signals (or data) quantized in the encoder, that is, signals Bkd, have a dynamic range from −0.5 to 0.5.

Thus, according to an embodiment, function Fcost can be written as:

$$Fcost ( xa , xq , Ak 0 ) = Ffid ( xa , xq ) + λ * Fdr ( Ak 0 ) \qquad [ Math 15 ]$$

$$with$$

$$λ a scalar factor .$$

In the same way as a fidelity function, for each training data item of index s of a given training batch, a regularization function may be calculated at the Nth conversion cycle only, or, as a variant, be calculated at at least one specific cycle C[n], for example at each of the N conversion cycles C[n]. Further, a regularization function calculated at a given cycle C[n] may be calculated from a data sequence obtained up to this cycle, and may be non-linear, for example correspond to a minimum or maximum value of a calculation performed on these data, or linear, for example correspond to a weighted sum of a calculation performed on these data.

The regularization function Fdr in function Fcost advantageously aims at ensuring the stability of the recurrent modulator for a given oversampling rate value N.

Of course, those skilled in the art will be capable of providing other regularization functions determined by functional and/or material properties of the converter to be manufactured.

In addition to the function Fcost determined by a fidelity function Ffid and, preferably, by at least one regularization function, constraints and/or regularization terms may be applied to the generic model.

Thus, according to an embodiment, at least one constraint and/or at least one regularization term is applied to the generic model, to the weights of the model, or to the data.

According to an embodiment, at least one constraint and/or at least one regularization (or regularization term) applied to the generic model is determined by a material property and/or a functional property that the converter to be manufactured needs to respect.

As an example, a constraint corresponds to a feature which is forced into the model, during the supervised deep learning. A constraint may be implemented by adding a layer to the model which has no hardware counterpart (or, in other words, no hardware version), by applying, for example, a mask to the weights of the model or by applying a function to layers of the model. A constraint may be applied to the data tensors of the model, or to the weights of the model. A constraint is, for example, a function or a layer which directly acts on the data or the weights that it receives, that is, which can modify the values of these data or of these weights.

As an example, a regularization aims at guiding the learning in order to obtain a desired result in the trained model or in its hardware counterpart. A regularization may be implemented by adding a layer to the model which will have no hardware counterpart and which will have the purpose of calculating quantities on the data transiting therethrough without modifying these data, these quantities then being used in the calculation of the cost function, for example by being added to the fidelity function. A regularization may also be implemented by applying a function to layers of the model. A regularization may be applied to the data tensors of the model, and is then for example referred to as an activity regularizer, or to the weights of the model, and is then for example referred to as a kernel regularizer. The layers or functions of regularization on the weights or data enable, for example, to assign additional penalties to the cost function, these penalties being defined by deviations between magnitudes calculated on the latent weights or the data of the model and expected values for these magnitudes.

According to an embodiment, a constraint applied to the model is determined by the maximum possible dynamic range at the output of each cell Cellk of the model. For example, this constraint corresponds to the addition of a clipping layer at the output of each cell Cellk, which clips (or saturates) the output signals of the cells Cellk when these signals come out of the maximum authorized dynamic range.

According to an embodiment, a constraint applied to the model is determined by a targeted robustness of the manufactured converter to temporal non-idealities, for example related to the kTC noise when the weights of the manufactured converter are implemented by capacitive elements or capacitive circuits. For example, this constraint corresponds to the addition, on each internal node of the encoder, of a data augmentation layer adding Gaussian random noise on this internal node.

According to an embodiment, a constraint applied to the weights of the model, in particular to the encoder weights, is determined by a sizing of the circuits (capacitive or resistive) implementing the weights. This constraint corresponds to the search for a common denominator for the encoder weights or a sub-group of encoder weights. The aim of this constraint is to find an adequate sizing of the weights of the model that favors the obtaining of a common denominator for all the values of converter weights or of a sub-group of converter weights. This constraint amounts to implementing a supervised deep learning using a quantization-aware training (QAT). Quantization-aware trainings (QAT) are well known and enable the learning of quantized WM weights (see [Math 8]), these quantized weights being derived from the latent weights, noted WM1. For example, the training to obtain quantized weights comprises a Q-step uniform quantization implemented during the feedforward phase, combined with a straight through estimator for the gradient during the back propagation phase. As an alternative example, those skilled in the art will also be capable of providing, instead of a straight through estimator, any proxy for the phase of back propagation of the gradient. As an example, a proxy enables to replace, for the calculation of the gradient, a non-derivable function used during feedforward, such as for example the quantization function, by an alternative function on which the gradient can be calculated. For example, the provided quantization function is based on function round( ) which rounds to the nearest integer the fractional part. The input dynamic range of function round( ) is set, for example, based on the maximum value Wlmax of the absolute values of the latent weights of the encoder, with:

$${W}^{l} max = max ( \vert {WM}^{l} \vert ) \qquad [ Math 16 ]$$

For example:

$$WM = qstep * round ( \frac{W {M}^{l}}{qstep} ) \qquad [ Math 17 ]$$

with qstep the quantization step. As an example, qstep is equal to 1/(round((2^{q-1})/W^{l}max)) and q is an integer used to set the granularity of the performed quantization and the maximum ratio of the largest to the smallest absolute weights. As another example, qstep is a value learned by using a weight W^{l}scale learned during the training, and is then for example equal to 1/(round((2^{q-1})/W^{l}scale)).

In the above example, quantization-aware supervised deep learning enables to find an adequate sizing of the weights of the model favoring the obtaining of a common denominator for all the weight values. This enables to implement the weights with switched capacitive elements, each corresponding to one or a plurality of identical unitary capacitive elements, each of the unitary capacitive elements having a same value determined by the common denominator obtained during the training. In another example, this enables to implement weights with resistors, each corresponding to one or a plurality of identical unitary resistors, each of the unitary resistors having a same value determined by the common denominator obtained during the training.

According to an embodiment, a regularization that can be applied to the model during the supervised deep learning is determined by a surface area of the converter to be manufactured, and, more particularly, aims at decreasing this surface area. For example, it is intended to introduce a regularization applying to the encoder weights which is similar to an L0 norm (representative of the number of non-zero values) or to any equivalent form, for example an L1 regularization under certain assumptions, to limit the number of electrical connections in the converter, or, in other words, to prune electrical connections in the converter.

According to an embodiment, a constraint applied to the model is determined by a surface area of the converter to be manufactured and, more particularly, aims at decreasing this surface area by masking connections in the encoder. For example, weights of the encoder model are masked during the learning to limit the number of effective connections between encoder cells, which results in a greater compactness of the final converter. For example, the matrix of latent weights WM1 is multiplied by a binary mask, that is, by a matrix of latent masking weights, so as to disable the corresponding connections. This binary mask is for example obtained by thresholding of a matrix of latent masking weights. To control the number of zero weights in the binary mask, a regularization function may depend on the number of zero weights after thresholding of the matrix of masking weights, and add a term to the cost function that will be determined by a deviation between the number of zero weights in the binary mask counted by the regularization function and a targeted or expected number of zero masking weights. According to an embodiment, rather than being determined by a targeted surface area for the converter to be manufactured, the constraint of applying a binary mask to weights of the model is determined by a targeted topology for the converter to be manufactured, and the mask is configured to remove data paths (or connections) in the model that do not correspond to any path in the targeted topology.

According to an embodiment, a constraint applied to the model is determined by a surface area of the converter to be manufactured and, more particularly, aims at decreasing this surface area. As an example, weight clipping techniques may be used to decrease the converter surface area.

According to an embodiment, a regularization applied to the model is determined by material properties of the converter to be manufactured and aims at avoiding the attenuation of the modulator signals. For example, this regularization is applied to the weights corresponding to the feedback path with a delay by one cycle of each cell Cellk, that is, for example to the weight Wapk1 with k equal to p of each cell Cellk of index k equal to p, for example to the weights Wa111, Wa221, and Wa331 in the example of FIG. 6. As an example, this regularization introduces a penalty added to the cost function when one or a plurality of these weights are smaller than 1. In other words, this regularization corresponds to a regularization function determining the cost function together with the fidelity function, and, for example, other regularization functions, for example, function Fdr. Still in other words, this regularization corresponds to a regularization function used in the calculation of the cost function.

According to an embodiment, one or a plurality of constraints applied to the model are determined by material properties of the converter to be manufactured, and aim at emulating static errors on the value of the weights effectively implemented in hardware fashion and the value of the corresponding weights of the model and/or of the finite gains of the operational amplifiers implementing in hardware fashion the adding and/or integration functions of the model. For example, each of these constraints is implemented by a layer with no hardware counterpart which acts on the data or weights of the model. For example, a data augmentation layer may be used to add an error to the effective weights of the model during the training or even feedforward phase. As another example, an augmentation layer may be used downstream of the adder of each of each Cellk, to introduce a non-unitary weighting modeling the gain error of the amplifier implementing the addition.

According to an embodiment, a constraint applied to the weights of the model (latent or quantized), and more particularly to the weights of the encoder model, is determined by functional properties of the converter to be manufactured, and aims at forcing the type, positive or negative, of at least certain feedbacks implemented in the converter to be manufactured. This constraint consists of forcing the sign of given weights of the encoder model to force negative and positive feedbacks in the model. For example, the sign of weights corresponding to negative feedbacks is forced to be a negative sign, and the sign of weights corresponding to positive feedbacks is forced to be a positive sign.

According to an embodiment, in addition to the constraints and/or applications applied to the model, at least some of which are determined by the material or functional properties of the converter to be manufactured, optionally a normalization layer is added at the output of the model. This normalization layer consists of adding a sizing factor (or weight) to the output of the decoder model, so as to adapt the dynamics of the converter model output to the index n of the current cycle C[n]. As an example, the normalization layer is configured so that the converter provides at each cycle a scaled output data item. According to an embodiment, a regularization function may be assigned to this normalization layer. For example, to smooth the reconstruction between each cycle, an L2 regularization is applied to the derivative of the absolute value of these sizing weights, so that these sizing weights have values which vary monotonically as a function of oversampling value N.

According to an embodiment, in addition to the constraints and/or regulations and/or weightings applied to the model, at least some of which are determined by material or functional properties of the converter to be manufactured, optionally learning strategies are applied to the supervised deep learning, or, in other words, are introduced into the supervised deep learning phase.

As an example, this or these learning strategies aim at ensuring a stable behavior of the model during the supervised deep learning.

According to an embodiment, one of these learning strategies consists of implementing one or a plurality of callback functions to set characteristics of the training phase, for example from one batch to the next, and/or from one training epoch to the next.

According to an embodiment, one of these learning strategies consists of selecting statistical parameters on the input data supplied to the model during the supervised deep learning phase. As an example, each training batch is selected or constructed from the training data, for example originating from a static database or generated on the fly, so that each training batch respects a statistical property. As an example, the input and output data distribution further enables to introduce an implicit regularization of the model, for example a regularization favoring a homogeneity of the converter performance over the entire dynamic range of the input signal.

According to an embodiment, one of these learning strategies concerns the initialization of the latent weights of the encoder model. For example, the latent weights of the encoder model are initialized to purely random values. As another example, the latent weights of the encoder model are initialized to values corresponding to the values of the weights of a reference topology. As another example, the latent weights of the encoder model are initialized with the values of corresponding weights of a reference topology if these weights of the reference topology are non-zero, and with a random value otherwise.

According to an embodiment, a callback function of “ReduceLROnPlateau” type is used on metrics representative of the desired specifications, for example relative to the hardware implementation and/or to the functionalities of the converter, at each end of a learning epoch. For example, this function aims at decreasing the learning rate when the considered metric no longer varies. As an example, the metric is representative of a material property of the converter to be manufactured. An example of a metric that can be used is determined by the ratio of the dynamic range DR of the parameter to be inferred to the maximum conversion error on this dynamic range DR (for example, the quantization error). This metric is representative of a maximum number of quantization steps usable without there being a quantization error on this dynamic range. For example, this metric can be expressed by the following formula [Math 18]:

$${MAX}_{resol} = {log}_{2} ( \frac{DR}{{max}_{s} \{ \vert xa [ s ] - xq [ s ] \vert \}} ) \qquad [ Math 18 ]$$

According to an embodiment, a callback function is used at the end of each learning epoch to randomly enable and disable data augmentation layers added on the inner nodes of the encoder, for example data augmentation layers introducing white noise on these inner nodes. This may enable a better convergence of the model during the learning.

According to an embodiment, a callback function used during the learning enables to progressively disable static binary masks applied to the latent weights of the encoder model, that is, this callback function enables to progressively reenable connections of the model during the learning, among the connections that have been masked at the beginning of the learning.

According to an embodiment, a callback function used during learning progressively decreases the value of q defined in connection with a quantization-aware training (QAT). For example, the learning can start without weight quantization for a first set of learning epochs, then weight quantization is enabled with a first quantization level q=q1 (with q1 an initial quantization level value) for a second set of learning epochs starting from the best set of latent weights obtained at the end of the first set of learning epochs, then, for subsequent sets of learning epochs, each set of learning epochs starts, for example, with the best set of latent weights obtained at the end of the previous set of learning epochs by reducing the value of q, until a desired value of q is obtained, determined by material properties of the converter to be manufactured.

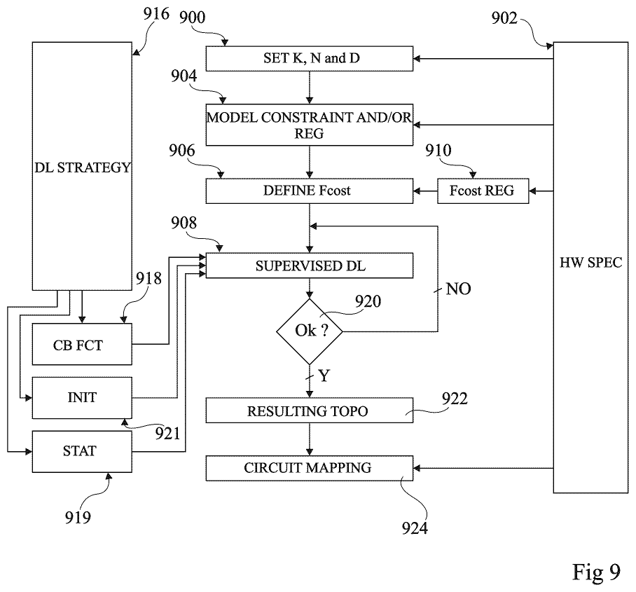

FIG. 9 schematically illustrates, in a flowchart, an embodiment of a method for designing (or sizing) a sigma-delta converter.

At a step 900 (block “SET K, N and D”), the hyperparameters of the model, that is, the number K of cells Cellk, the oversampling rate N, and the value D defining the delays, are defined by the designer. As an example, other hyperparameters of the model may be defined by the designer at this step, such as for example the number of possible output values of each quantizer or, in other words, the quantization resolution of the outputs Bkd.

For example, the value of number N can be determined by a hardware constraint from a specification 902 (“HW SPEC” block) defining hardware and/or functional constraints that the converter should meet, as shown in FIG. 9.

For example, the value of number D may be at least partly determined by these specifications. For example, number D may be decreased with the maximum surface area targeted for the converter. Indeed, the greater number D, the greater the number of connections and of weights of the model, and thus the larger the surface area of the converter.

For example, number K may be at least partly determined by specifications 902, for example by a maximum surface area targeted for the converter and/or by a targeted conversion accuracy for the converter. For example, the greater number K, the larger the converter will be, and/or the greater number K, the lower the conversion error, for example linked to thermal noise and to the quantization error, will be. As an example, number K may be at least partly determined by the order M of the converter to be manufactured, K being preferably greater than or equal to M.

Although this is not illustrated in FIG. 9, step 900 further comprises a step of determination of a filter (or decoder) model based on recurrent neural networks, so as to obtain, at the end of step 900, a converter model. As an example, the filter comprises one or a plurality of successions (cascaded) of simple recurrent neural networks. An example of a filter model for an analog-to-digital converter has been described in relation with FIG. 8. Those skilled in the art will be capable of providing other models of filter modeled based on recurrent neural networks, for example based at least on simple recurrent neural networks, for an analog-to-digital converter, or even for analog-to-information converters taking as an input an analog signal and outputting information relative to this signal (frequency, amplitude, etc.).

At an optional next step 904 (block “MODEL CONSTRAINT AND/OR REG”), constraints and/or regularizations are directly added to the converter model. For example, these constraints and/or regularizations are added in the form of layers having no hardware counterpart in the converter which will be manufactured, in the form of functions applied to layers of the model, or in the form of masks applied to weights of the model. For example, at least one regularization may be applied to the model in the form of an additional term in the cost function.

According to an embodiment, at least one constraint and/or at least one regularization applied to the generic model is determined by a material property and/or a functional property that the converter to be manufactured needs to respect, as illustrated in FIG. 9 by an arrow from block 902 to block 904.

For example, at least one constraint and/or at least one regularization applied to the generic model is determined by saturation values of the inner signals of the modulator and corresponds, for example, to the addition of clipping layers to the model.

For example, at least one constraint applied to the generic model is determined by a target robustness of the converter to temporal non-idealities, and consists, for example, of inserting data augmentation layers to model the noise in the converter.

For example, at least one constraint applied to the generic model is determined by an implementation of the weights in a quantized form, and corresponds, for example, to an implementation of the deep learning by using a quantization-aware training. In other words, this constraint corresponds to the addition of a quantization layer to the latent weights of the model.

For example, at least one constraint applied to the generic model is determined by a surface area targeted for the converter to be manufactured, and corresponds, for example, to the application of at least one binary mask to weights of the model and/or to the implementation of a weight clipping technique.

For example, at least one constraint applied to the generic model is determined by errors on the finite gains of operational amplifiers that will be used to implement the converter and corresponds, for example, to the addition of an augmentation layer downstream of the adder of each cell Cellk, to introduce a non-unitary weighting modeling the finite gain error of the amplifier implementing the addition.

For example, at least one constraint applied to the generic model is determined by targeted maximum static errors on component values implementing the weights of the model and corresponds, for example, to the adding of errors to weights of the model.

For example, at least one constraint applied to the generic model is determined by a targeted converter or modulator topology, and consists of masking weights of the generic model to remove the data paths in the model which correspond to no data path in the target topology.

For example, at least one constraint applied to the generic model is determined by the direction of the data paths in the converter to be manufactured (direct paths or feedback paths), and consists of forcing the signs of certain weights of the generic model to implement positive and/or negative feedback loops in the converter to be manufactured.

For example, at least one constraint applied to the generic model is determined by a maximum targeted surface area, and consists of masking weights of the encoder to decrease the number of data paths in the model, which in turn amounts to decreasing the number of connections in the manufactured converter, and thus its surface area.

For example, at least one regularization applied to the model is determined by a maximum targeted surface area, and consists, for example, of an L1 regularization to limit the total number of weights used.

For example, at least one regularization applied to the model is determined by an output dynamic range of the converter to be manufactured. For example, an L2 regularization may be implemented on the derivative of the absolute values of the sizing factors, or weights, of a weighting layer added at the output of the model.

In a subsequent step 906 (block “DEFINE Fcost”), a cost function is defined for the next supervised deep learning step 908 (block “SUPERVISED DL”). The definition of function Fcost consists of defining a fidelity function Ffid, from which function Fcost is expressed.

Preferably, function Fcost is determined by function Ffid and by at least one regularization function, as illustrated in FIG. 9 by block 910 (block “Fcost REG”) indicating that the cost function Fcost determined at step 906 is partly determined by a regularization function.

For example, function Fcost is partly determined based on a regularization function determined by a material property and/or a functional property of the converter to be manufactured, as illustrated in FIG. 9 by the arrow from block 902 to block 910. For example, function Fcost is partly determined based on a regularization function, for example Fdr, determined by a maximum excursion of the output signals of each cell Cellk of the modulator, and/or, for example, by a regularization function adding a penalty to the cost function when certain weights, for example the weights Wapk1 of each cell Cellk of index k equal to p, are smaller than 1.

At the next step 908, the generic model of the converter is trained by the implementation of a supervised deep learning.

As previously mentioned, learning strategies may be provided during the supervised deep learning, as illustrated by a block 916 (“DL STRATEGY” in FIG. 9).

According to an embodiment, at least one learning strategy corresponds to a callback function 918 (block “CB FCT”), as illustrated in FIG. 9 by an arrow from block 916 to block 918. The callback function is applied at learning step 908, that is, used during step 908, as illustrated in FIG. 9 by an arrow from block 918 to block 908. Examples of such callback functions have been given previously.

According to an embodiment, at least one learning strategy corresponds to a statistical property 919 (block “STAT”) applied to, or imposed on, the training data, as illustrated in FIG. 9 by an arrow from block 919 to block 918. As an example, each training batch is selected or constructed from the training data so that each training batch respects a statistical property. For example, to train a converter model configured to convert a DC analog signal into its digital counterpart, each training batch is constructed so that the average of the absolute values of the training data forming it is the same in all training batches, and is, for example, equal to half the positive input dynamic range of the converter to be manufactured.

According to an embodiment, at least one learning strategy corresponds to an initialization of the latent weights of model 921 (block “INIT”), and corresponds to a way of initializing the latent weights of the model as illustrated by an arrow from block 921 to block 908 in FIG. 9. Various ways of initializing the latent weights of the model have been previously described, for example randomly and/or based on the weights of a reference topology and/or based on the weights of a model obtained at the end of a previous step 908.

Training step 908 is then implemented. It is during training step 908 that the various learning strategies are applied, such as for example the callback functions and/or the statistical properties defined on the training data and/or the initialization choices for the latent weights of the model.

At the end of one or a plurality of training epochs 908, in a subsequent step 920 (block “Ok?”), it is checked whether the obtained model, that is, the weights of the model which are obtained after the implementation of a step 908, satisfy the material and/or functional properties defined for the converter to be manufactured. In other words, this step 920 consists in checking whether or not a stop criterion for the training has been reached.

If this is not the case (output NO of block 920), step 908 is implemented again by using as an initial model the trained model obtained at the end of the previous step 908, or a trained model obtained at the end of one of the epochs of the previous step 908, or a model having different conditions of initialization of the latent weight, for example a latent weight initialization which is random and independent of any previously-learned topology or any reference topology. As another example, step 908 may be implemented again from a generic model obtained by implementing steps 900, 904, 906, and 916 again, but with different constraints and/or regularizations and/or learning strategies.

If this is the case (output Y of block 920), step 920 is followed by step 922 (block “RESULTING TOPO”). At this step 922, one has a trained model which satisfies the material properties and/or the functional properties which have determined the constraints and regularizations applied to the generic model at steps 904 and 906. This model defines, or determines, a topology of the converter to be manufactured, that is, for example, the connections (or data paths) in the converter to be manufactured, the weights to be applied to each inner signal of the converter, the delays to be applied, and the sums to be implemented.

In a subsequent step 924 (block “CIRCUIT MAPPING”), the topology of step 922, that is, the trained model received at step 922, is mapped onto, or transformed into, hardware. For example, each data path of the trained model is implemented by an electrical connection, and/or the weights are implemented by resistive or capacitive components and/or the delays are implemented by corresponding clock signals, sums between data are implemented by adder circuits, for example based on operational amplifiers, etc.

Preferably, during this step of transformation of the trained model into a circuit, the material properties and/or functional properties of the converter to be manufactured which have been used at steps 900, 904, 906, 908, and 910 are respected, as illustrated in FIG. 9 by an arrow from block 902 to block 924. For example, if a regularization based on the dynamic range of the converter signals has been applied to the model at step 904, the circuit is designed to respect this dynamic range. As another example, if the training is quantization-aware, the weights will each be implemented from a unitary resistive or capacitive component. For example, if the model used during the training comprises constraint layers for emulating the maximum gain of the operational amplifiers implementing sums in the converter to be manufactured, the operational amplifiers effectively used for the converter circuit have this maximum gain value.

Finally, in a subsequent step, not shown, the circuit obtained at the end of step 924 is manufactured.

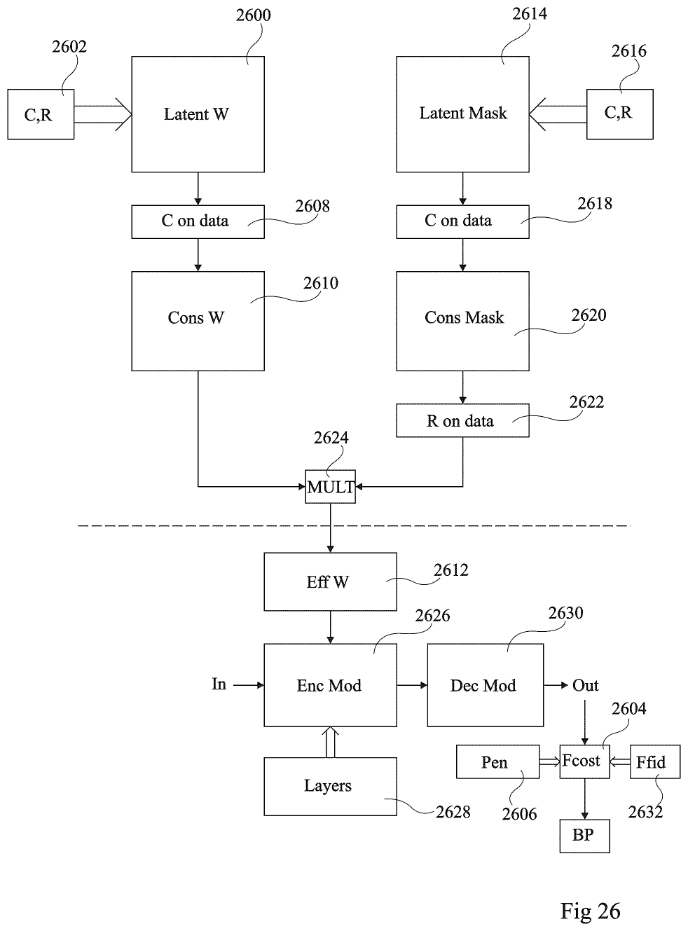

FIG. 26 illustrates, schematically, generally, and in the form of blocks, an example of how constraints and regularizations can be applied to the model during the training. In other words, FIG. 26 illustrates steps of the method described in relation with FIG. 9.

In this FIG. 26, a block 2600 (“Latent W”) represents the latent weights of the encoder. As illustrated by a block 2602 (“C,R”), regularization functions and/or constraints may be applied to these latent weights. For example, a constraint is applied to the latent weights and will directly act on the values of the latent weights, for example by limiting the maximum value that these latent weights can take. For example, an L1 regularization is attached to the latent weights of the encoder, which will assign a penalty term to the cost function. In FIG. 26, the cost function is represented as a block 2604 (“Fcost”) and the penalty or penalties assigned to the cost function are shown in the form of a block 2606 (“Pen”).

Further, constraints may be applied to the latent weights of the encoder by means of one or a plurality of layers which will have no hardware counterpart. In FIG. 26, these constraints are represented by a block 2608 (“C on Data”) receiving the latent weights (block 2600), to which constraints and/or regularizations (block 2602) may have been directly applied, and providing constrained weights represented in the form of a block 2610 (“Cons W”) in FIG. 26.

For example, block 2608 comprises such a constraint layer implementing the weight quantization. This constraint layer receives latent weights 2600, and delivers quantized weights. The constrained weights 2610 will then be quantized weights.

For example, when it is aimed at implementing weights based on capacitive elements, block 2608 may comprise a constraint layer emulating the dispersion of capacitance values linked to the manufacturing of these capacitive elements. This layer will add fixed dispersions to the data that it receives, these data being, for example, the quantized weights supplied by the constraint layer in the above example.

The constrained latent weights 2610 thus obtained can then directly correspond to the effective weights of the encoder model, the latter being represented by a block 2612 (“Eff W”) in FIG. 26.

However, as shown in the example in FIG. 26, these constrained latent weights 2610 can be multiplied by a mask, the result of this multiplication then corresponding to the effective weights 2612.

For example, in FIG. 26, latent mask weights shown in the form of a block 2614 are provided. In the same way as for the latent weights 2600 of the encoder, constraints and/or regularizations may be directly applied to the latent mask weights 2614. In FIG. 26, these constraints and/or regularizations directly applied to latent mask weights 2614 are represented in the form of a block 2616 (“C,R”).

At least one constraint is applied to the latent mask weights 2614 by a layer with no hardware counterpart, represented in FIG. 26 by a block 2618 (“C on data”). This layer 2618 receives the latent mask weights 2614, and provides constrained latent mask weights represented in the form of a block 2620 (“Cons Mask”) in FIG. 26. For example, layer 2618 performs a level thresholding on weights 2614. In practice, the constrained latent mask weights 2620 correspond to a binary mask.

To control binary mask 2620, for example the ratio of zero weights in binary mask 2620, one or a plurality of regularization functions 2616 may be applied to the latent mask weights 2614, and/or one or more regularization functions 2622 (block “R on data”) may be applied to the weights 2620 (that is, the binary mask). In practice, when provided, these regularizations do not modify the value of the weights of binary mask 2620. For example, a regularization function 2622 counts the number of zero weights in binary mask 2620, and assigns a penalty 2606 proportional to the deviation between the counted number and a desired number.

The constrained latent weights 2610 of the encoder are then multiplied by binary mask 2620, as shown by a block 2624 (“Mult”) in FIG. 26, to obtain the effective weights 2612.

These effective weights are used in the encoder model, shown in the form of a block 2626 (“Enc Mod”) in FIG. 26, and correspond to the weights which will be physically implemented when the trained model will be satisfactory in terms of target performance.

Further, layers with no hardware counterpart may be applied, that is, added, to encoder model 2626. In FIG. 26, these layers with no hardware counterpart are shown in the form of a block 2628 (“Layers”). As an example, one or a plurality of layers 2628 correspond to constraint layers. For example, a constraint layer 2628 enables to saturate signals in encoder model 2626 when these signals exceed a threshold. As another example, one or a plurality of layers 2628 correspond to data augmentation layers. For example, a data augmentation layer 2628 enables to add temporal Gaussian noise to signals of encoder model 2626.

In FIG. 26, the decoder model is shown in the form of a block 2630 (“Dec Mod”). This block receives signals from encoder model 2626, and delivers output data Out. Encoder model 2626 receives input data In.

Although this is not detailed in FIG. 26, regularization functions and/or normalizations may be applied to decoder model 2630.

During the training, block 2626 receives input data In and block 2630 delivers the corresponding output data Out.

Function Fcost is then calculated from data Out. More particularly, function Fcost is calculated based on a fidelity function 2632 (“Ffid”) and, where present, based on the penalties 2606 assigned to the cost function by regularization functions. Function Fcost is then representative of an error between the data Out obtained at the output of the model, and the data expected for the inputs In supplied to the model.

This is followed by an error backpropagation step BP. The weights of the model are for example updated during this step BP.

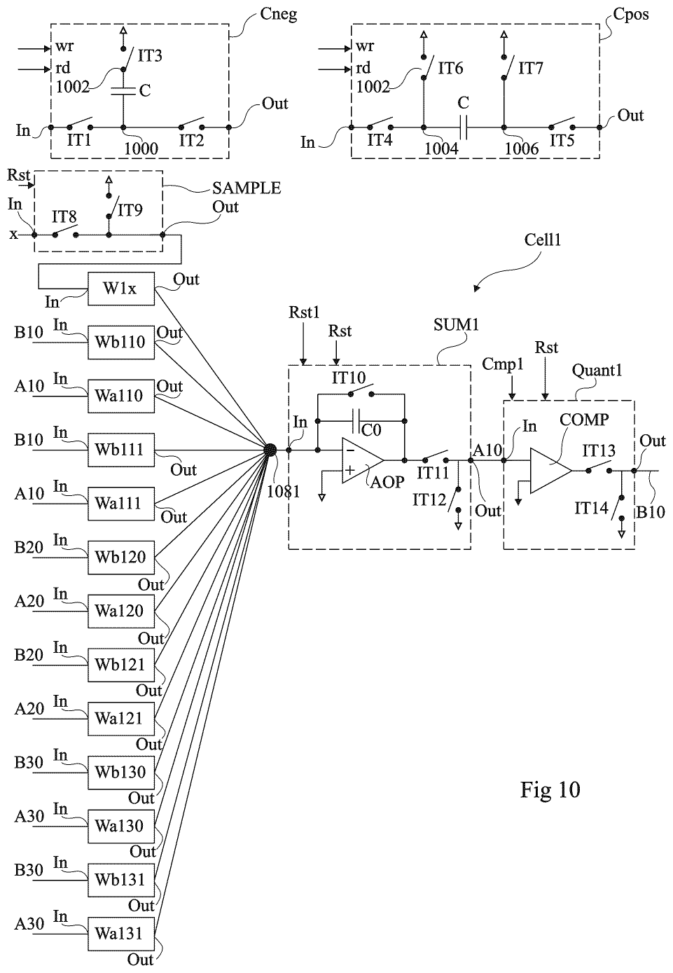

FIG. 10 generically illustrates an example of hardware implementation of a trained encoder model when the weights are implemented based on capacitive components.

More specifically, the top of FIG. 10 shows the implementation of any weight W, that is, any of the weights Wpx, Wapkd, or Wbpkd of a cell Cellk.

As shown at the top left in FIG. 10, when weight W is negative, the latter is implemented by a circuit Cneg comprising a capacitive element C having a value equal to the absolute value of the weight multiplied by the value of a unitary capacitive element C0. Capacitive element C is connected between two nodes 1000 and 1002. A switch IT1 connects node 1000 to an input In of circuit Cneg, and a switch IT2 connects node 1000 to an output Out of circuit Cneg. A switch IT3 connects node 1002 to a reference potential.

Each circuit Cneg comprises two control inputs wr and rd. Switch IT3 is on when one or the other of its inputs wr and rd receives an active signal. Switch IT1 is controlled by a signal corresponding to the signal on its input wr with, optionally, a delay to limit charge injections, and is on when this delayed signal is active, off otherwise. Switch IT2 is controlled by a signal corresponding to the signal on its input rd with, optionally, a delay to limit charge injections, and is on when this delayed signal is active, and off otherwise.

As shown at the top right of FIG. 10, when weight W is positive, the latter is implemented by a circuit Cpos comprising a capacitive element C having a value equal to the absolute value of the weight multiplied by the value of a unitary capacitive element C0. Capacitive element C is connected between two nodes 1004 and 1006. A switch IT4 connects node 1004 to an input In of circuit Cpos, and a switch IT5 connects node 1006 to an output Out of circuit Cpos. A switch IT6 connects node 1004 to reference potential, and a switch IT7 connects node 1006 to the reference potential.

Each circuit Cpos comprises two control inputs wr and rd. Switch IT4 is controlled by a signal corresponding to the signal on its input wr with, optionally, a delay to limit charge injections, and is on when this delayed signal is active, off otherwise. Switch IT5 is controlled by a signal corresponding to the signal on its input rd with, optionally, a delay to limit charge injections, and is on when this delayed signal is active, off otherwise. Switch IT6 is on when the signal on its input rd is active, and off otherwise. Switch IT7 is on when the signal on its input wr is active, and off otherwise.

Further, the bottom of FIG. 10 shows the implementation of a cell Cellk of index k equal to 1 in the example of FIG. 10, in an example of a converter model where K is equal to 3 and D is equal to 2.

In this drawing, each circuit Cneg or Cpos implementing a corresponding weight is represented by a block having the same reference as the weight that it implements. Each circuit Cneg or Cpos implementing a weight Wapkd or Wbpkd receives on its input In the signal Ak0, respectively Bk0, from cell Cellk.

The signals supplied to the inputs wr and rd of circuits Cpos and Cneg enable to implement the data transfer between the K cells Cellk during a same conversion cycle C[n], and between two successive conversion cycles, by implementing the corresponding d-cycle delays.

Each cell Cellk further comprises a circuit Sample. An input In of circuit Sample receives signal x. In each cell Cellk, the output Out of circuit Sample is connected to the input of the circuit Cpos or Cneg implementing the cell weight Wkx. Each circuit Sample comprises a switch IT8 connected between the input In and the output Out of circuit Sample, and a switch IT9 connected between the output Out of circuit Sample and the reference potential.

Each circuit Sample further receives a control signal Rst. Switch IT8 is configured to be on when signal Rst is inactive, and off otherwise, switch IT9 being configured to be on when signal Rst is active, and off otherwise. As an example, signal Rst is switched to the active state during a reset phase prior to each conversion over N cycles.

Each cell Cellk comprises a circuit SUMk. For example, the cell Cell1 shown in FIG. 10 comprises a circuit SUM1. Each circuit SUMk comprises an operational amplifier AOP. The amplifier AOP of cell Cellk has its inverting input (−) connected to an input In of the circuit SUMk of the cell, this input In being connected to the node 108k (1081 in FIG. 10, which represents cell Cell1, or, in other words, the cell Cellk of index k equal to 1) of the cell. Amplifier AOP has its non-inverting (+) input connected to the reference potential. A unitary capacitive element C0 is connected between the output and the inverting input of amplifier AOP. A switch IT10 is connected in parallel to unitary capacitive element C0. A switch IT11 couples the output of the amplifier AOP of circuit SUMk to the output Out of circuit SUMk. A switch IT12 is connected between the output Out of circuit SUMk and the reference potential.

Each circuit SUMk receives signal Rst. Switch IT11 is on when signal Rst is inactive, off otherwise. Switch IT12 is on when signal Rst is active, off otherwise.

Each circuit SUMk further receives a control signal Rstk from the cell Cellk to which this circuit belongs. For example, in FIG. 10, circuit SUM1 receives signal Rst1. Switch IT10 is on when the signal Rstk received by the circuit SUMk to which it belongs is active, off otherwise. For example, in FIG. 10, circuit SUM1 receives signal Rst1.

In each cell Cellk, the output Out of the circuit SUMk of the cell supplies the signal Ak0 of the cell. In the example of FIG. 10, the circuit SUM1 of cell Cell1 supplies signal A10 at its output Out.

To supply signal Bk0, each cell Cellk comprises a circuit Quantk having its input In connected to the output Out of the circuit SUMk of the cell, and its output Out supplying the signal Bk0 of the cell. In the example shown in FIG. 10, the circuit Quant1 of cell Cell1 has its input In connected to the output Out of the circuit SUM1 of cell Cell1, and its output Out supplying signal B10.

Each circuit Quantk comprises a threshold comparator COMP, having an input, for example non-inverting, connected to its input In, and having another input, for example inverting, connected to the reference potential. The comparator COMP of each circuit Quantk is clocked by a control signal Cmpk received by this circuit, and for example active in the high state. For example, the output of circuit COMP is updated when its clock signal is active. For example, in FIG. 10, circuit Quant1 receives signal Cmp1.

Further, each circuit Quantk comprises a switch IT13 coupling the output of comparator COMP to the output of circuit Quantk, and a switch IT14 coupling the output Out of circuit Quantk to the reference potential. Each circuit Quantk receives control signal Rst. Switch IT13 is on when signal Rst is inactive, off otherwise. Switch IT14 is on when signal Rst is active, off otherwise.

In FIG. 10, the output signals of each of the 3 cells Cell1, Cell2, and Cell3, which are supplied to the corresponding circuits Cneg and Cpos of the shown cell Cell1, have been shown.

The provision of the control signals received by the inputs rd and wr of circuits Cneg and Cpos, of the K signals Cmpk, of the K signals Rstk, and of the signal Rst of an encoder with K cells CellK to implement the data transfers (charges in the example of FIG. 10) between the K cells during a cycle of given index n, by implementing the delays by d cycles, and so as to obtain the operation described in relation with FIGS. 5, 6, and 7, is within the abilities of those skilled in the art based on the present disclosure.

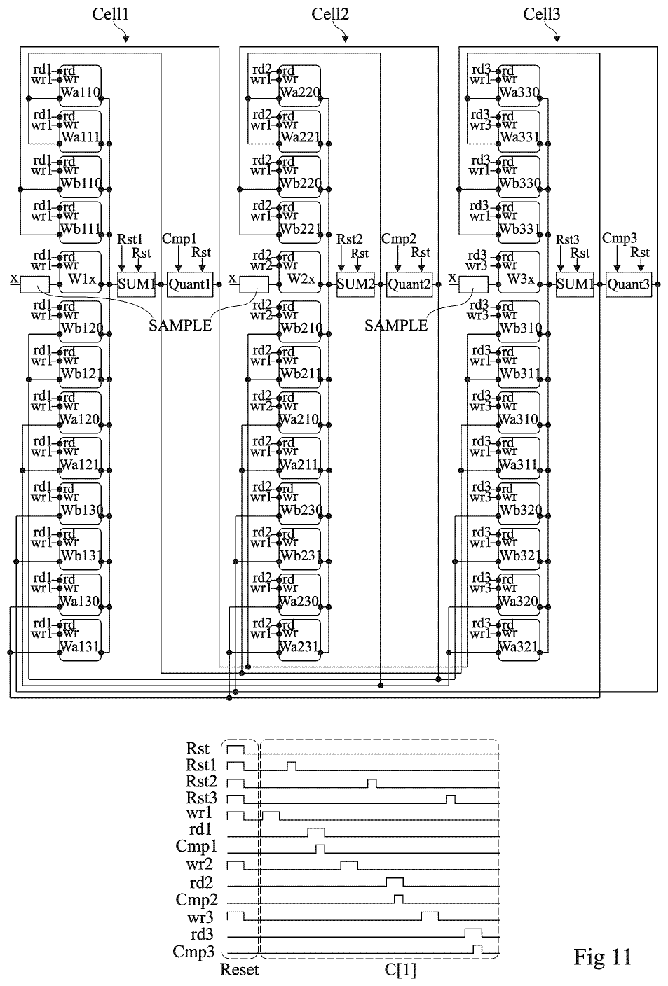

FIG. 11 illustrates, at the top, a more detailed implementation of a trained modulator model, in the case where K is equal to 3 and D is equal to 2, and, at the bottom, timing diagrams of the control signals, in an example where each of the control signals is active in the high state. More particularly, these timing diagrams illustrate a reset phase Reset and a first cycle C[1] of a conversion over N cycles C[n].

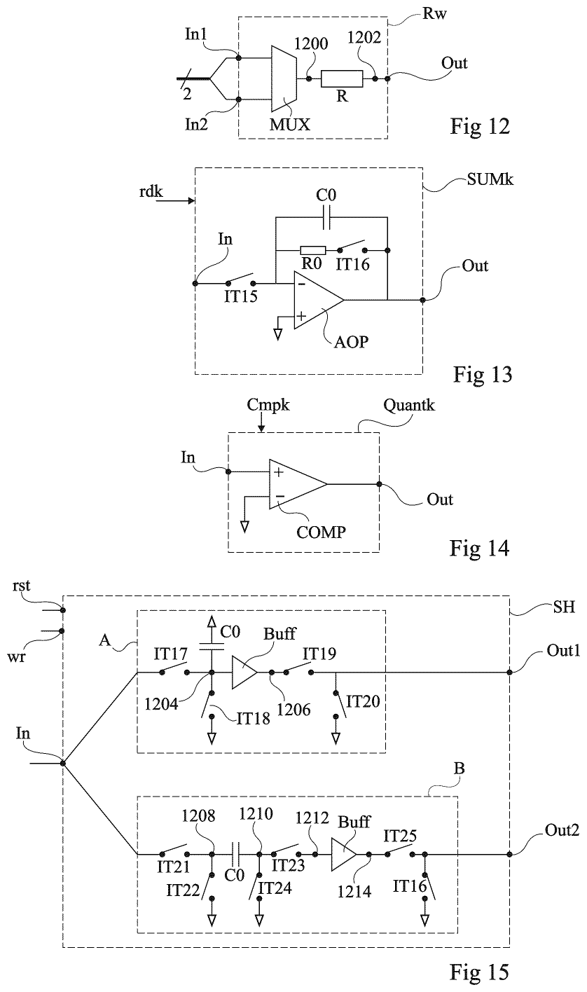

FIGS. 12, 13, 14, 15, and 16 generically illustrate an example of hardware implementation of a trained encoder model when the weights are implemented based on resistive components.

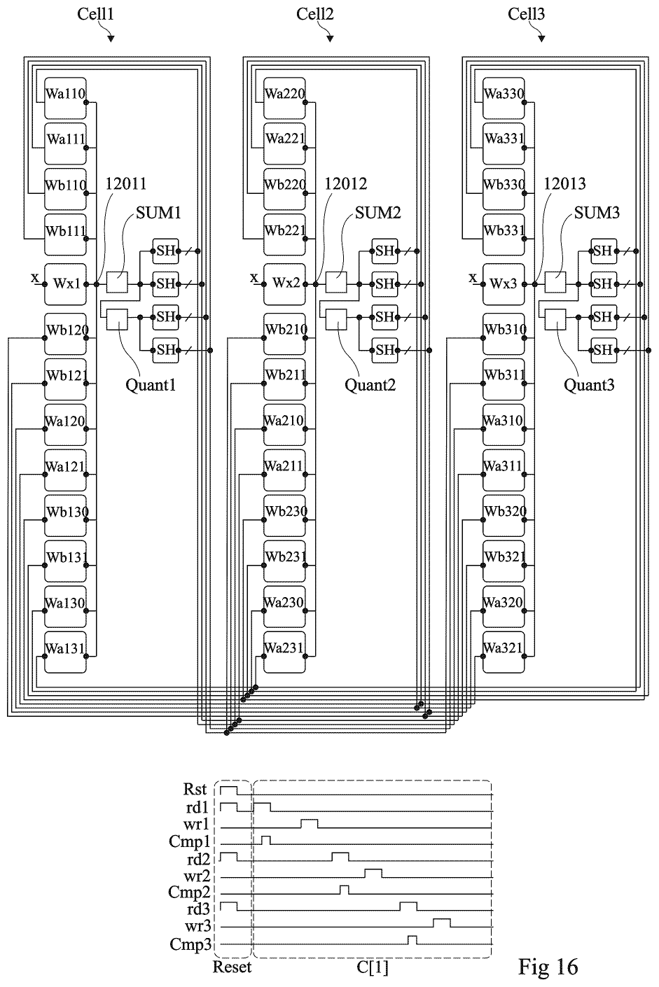

More particularly, as illustrated in FIGS. 12 and 16, each weight of a cell Cellk, that is, any of the weights Wpx, Wapkd, or Wbpkd of the cell, is implemented by a circuit Rw. Circuit Rw comprises a resistor R having a value equal to the value of a unitary resistor R0 divided by the value of the weight. Resistor R is connected between two nodes 1200 and 1202, node 1202 being connected to an output Out of circuit Rw. Further, each circuit Rw comprises two inputs In1 and In2 and one multiplexer MUX having its two inputs connected to respective inputs In1 and In2, and its output connected to node 1200. When the weight implemented by circuit Rw is negative, the multiplexer couples input In1 to node 1200, and, conversely, when the weight implemented by circuit Rw is positive, the multiplexer couples input In2 to node 1200. Although this is not illustrated in FIG. 12, multiplexer MUX receives a binary control signal having its state determined by the sign of the implemented weight. As an example, this control signal is supplied by a control circuit, not shown, for example a control circuit supplying a control signal to each of the multiplexers MUX of circuits Rw.

FIG. 16 shows the hardware implementation of a generic encoder model, in the example of a converter model where K is equal to 3 and D is equal to 2.

In this drawing, each circuit Rw implementing a corresponding weight is represented by a block having the same reference as the weight that it implements. In each cell Cellk, each circuit Rw has its output Out connected to a node 1201k of the cell. For example, in FIG. 16, the circuits Rw of cell Cell1 all have their outputs connected to the node 12011 of the cell. Further, each circuit Rw receives on its inputs In1 and In2 a pair of signals corresponding to an output signal of one of the cells Cellk to which the weight implemented by this circuit is to be applied.

Each cell Cellk comprises a circuit SUMk, as shown in FIG. 16, an implementation of a circuit SUMk being shown in FIG. 13.

Each circuit SUMk comprises an operational amplifier AOP and a switch IT15 coupling the inverting input (−) of the amplifier AOP of cell Cellk to the input In of the circuit SUMk of the cell, this input In being connected to cell node 1008k. Amplifier AOP has its non-inverting input (+) connected to the reference potential. A unitary capacitive element C0 is connected between the output and the inverting input of amplifier AOP. A series association of a switch IT16 and of a unitary R0 resistor is connected in parallel with capacitive element C0. The amplifier output is connected to the output Out of circuit SUMk.

Each circuit SUMk receives a control signal rdk. Switch IT15 is on when signal rdk is active, off otherwise. Switch IT16 is on when signal rdk is active, off otherwise.

As shown in FIG. 16, each cell Cellk comprises a circuit Quantk having its input In connected to the output Out of the circuit SUMk of the cell, and an output Out, an implementation of a circuit SUMk being illustrated in FIG. 14.

Each circuit Quantk comprises a threshold comparator COMP having an input, for example non-inverting (+), connected to its input In, and having its other input, for example inverting (−), connected to the reference potential. The comparator COMP of each circuit Quantk is clocked by a control signal Cmpk received by this circuit. For example, the output of circuit COMP is updated when its clock signal is active.

As shown in FIG. 16, each cell Cellk further comprises a plurality of circuits SH, each delivering a corresponding output signal of cell Cellk. An implementation of a circuit SH is shown in FIG. 15. In this implementation, each output signal of a circuit SH, corresponding to an output signal of a cell Cellk, corresponds to a pair of signals supplied to the inputs In1 and In2 of a circuit Rw corresponding to a weight to be applied to this cell output signal, and only one of the signals of the pair of signals is selected by the multiplexer of the circuit Rw according to the sign of the weight.

Each circuit SH comprises an input In and two outputs Out1 and Out2, and is configured to store in capacitive elements an image of the voltage received on its input In. Further, according to the way in which each circuit SH is controlled by a control signal received on its input rst and a control signal received at its input wr, each circuit SH enables to implement or not a delay by one cycle C[n] between its input and its output. Each circuit SH then enables, when its outputs Out1 and Out2 are connected to the respective inputs In1 and In2 of a circuit Rw, to implement the sign of the weight corresponding to this circuit Rw, by selecting with the multiplexer MUX of circuit Rx one or the other of the two inputs In1 and In2.

More particularly, as shown at the bottom of FIG. 15, each circuit SH comprises a circuit A coupling the input In of circuit SH to output Out1, and a circuit B coupling the input In of circuit SH to output Out2.

Circuit A comprises a unitary capacitive element C0 connected between a node 1204 and the reference potential. A switch IT17 couples input In to node 1204, and a switch IT18 couples node 1204 to the reference potential. A unitary analog buffer circuit Buff couples node 1204 to node 1206. A switch IT19 couples node 1206 to output Out1, and a switch IT20 couples output Out1 to the reference potential.

Switch IT17 is on when the signal received by input wr is active, off otherwise. Switches IT18 and IT20 are on when the signal received by input rst is active, off otherwise, switch IT19 being on when signal rst is inactive, off otherwise.

Circuit B comprises a unitary capacitive element C0 connected between a node 1208 and a node 1210. A switch IT21 couples input In to node 1208, a switch IT22 couples node 1208 to the reference potential, a switch IT23 couples node 1210 to node 1212, and a switch IT24 couples node 1210 to the reference potential. An analog unitary buffer Buff couples node 1212 to node 1214. A switch IT25 couples node 1214 to output Out2, and a switch IT26 couples output Out2 to the reference potential.

The switch IT21 controlled by a signal corresponding to the signal received by the input wr to which, preferably, a delay has been applied to avoid charge injections, is on when this delayed signal is active, off otherwise. Switches IT22 and IT23 are on when the signal received by input wr is inactive, off otherwise. Switch IT24 is on when the signal received by input wr is active, or when a signal corresponding to the signal received by input rst to which a delay is preferably applied is active, and off otherwise. Switch IT25 is on when the signal received by input rst is inactive, off otherwise, switch IT26 being on when the rst signal is active, off otherwise.

In FIG. 16, each cell Cellk comprises two circuit SHs connected to the output Out of the circuit SUM of the cell, a first one of the two circuits delivering the output signal Ak0 of the cell, and the other of the two circuits supplying cell signal Ak1. Further, each Cellk comprises two other circuits SH connected to the output Out of the circuit Quantk of the cell, a first one of the two circuits supplying the output signal Bk0 of the cell, and the other of the two circuits supplying cell signal Bk1. For example, each circuit SH delivers a pair of signals having identical absolute values but opposite signs, and the multiplexer of the circuit RW to which this pair of signals is delivered enables to select one of the two signals, which amounts to selecting the sign of the weight.

At the bottom of FIG. 16, timing diagrams illustrate modulator control signals, in an example where each of the control signals is active in the high state. More particularly, the timing diagrams illustrate a reset phase Reset and a first cycle C[1] of a conversion over N Cycles C[n]. In this example:
the first circuit SH from the top in cell Cell1 receives signals wr1 and Rst on its respective inputs wr and rst;
the second circuit SH from the top in cell Cell1 receives signals wr3 and Rst on its respective inputs wr and rst;
the third circuit SH from the top in cell Cell1 receives signals wr1 and Rst on its respective inputs wr and rst;
the fourth circuit SH from the top in cell Cell1 receives signals wr3 and Rst on its respective inputs wr and rst;
the first circuit SH from the top in cell Cell2 receives signals wr2 and Rst on its respective inputs wr and rst;
the second circuit SH from the top in Cell2 receives signals wr3 and Rst on its respective inputs wr and rst;
the third circuit SH from the top in cell Cell2 receives signals wr2 and Rst on its respective inputs wr and rst;
the fourth circuit SH from the top in cell Cell2 receives signals wr3 and Rst on its respective inputs wr and rst;
the four circuit SHs of cell Cell3 receive signals wr3 and Rst on their respective inputs wr and rst;
circuit SUM1 receives control signal rd1;
circuit SUM2 receives control signal rd2;
circuit SUM3 receives control signal rd3;
circuit Quant1 receives control signal Cmp1;
circuit Quant2 receives control signal Cmp2; and
circuit Quant3 receives control signal Cmp3.

It should be noted that the implementation of FIGS. 12 to 16 enables, when the values of the resistors R of circuits Rw are programmable, to program the modulator of FIG. 16 so as to be able to implement different trained models of modulators with K cells. This may enable, for example, to rapidly test a hardware implementation of a trained modulator model, without having to design a dedicated circuit. More generally, a programmable modulator topology of the type of that in FIG. 16, with a given value of K and a given value of D, may be programmed with trained modulator models in which K is smaller than or equal to this given value of K and/or D is smaller than or equal to this given value of D. In other words, this programmable topology is similar to an FPGA (Field Programmable Gate Array), but is dedicated to being programmed based on the trained model of a modulator based on a succession of cells Cellk.

Similarly, in the implementation of FIGS. 10 and 11, when the capacitance values of circuits Cneg, Cpos, Sumk, and Quantk are programmable, and each weight is implemented by a circuit Cneg, a circuit Cpos, and a multiplexer selectively routing a received signal to one or the other of circuits Cneg or Cpos according to the sign of the considered weight, the modulator is then programmable. As an example, a programmable capacitive element may be implemented by a bank of capacitive elements selectable in parallel, for example by a bank of dichotomously weighted capacitive elements. This enables to be able to program different trained modulator models, so as, for example, to quickly test a hardware implementation of a trained model of modulators with K cells without having to design a dedicated circuit. More generally, a programmable modulator topology of the type of that in FIG. 11, with a given value of K and a given value of D, may be programmed with trained modulator models in which K is smaller than or equal to this given value of K and/or D is smaller than or equal to this given value of D. In other words, this programmable topology is similar to an FPGA (Field Programmable Gate Array), but is dedicated to being programmed based on the trained modulator model based on a succession of cells Cellk.

In the examples of implementations described hereabove in relation with FIGS. 10 to 16, the weights and paths have all been shown. In practice, when it is aimed at a hardware implementation by a dedicated circuit, when a weight is zero, the circuit corresponding to the implementation of this weight as well as the connections associated with this circuit are omitted.

An example of implementation of the previously-described method will now be described.

In this example, the manufacturing of a sigma-delta converter of order M equal to 3 is desired, the converter being of cascaded integrator feed-forward (CIFF) type.

The generic encoder model 200 comprises, in this example, K equals 4 cells Cellk, with Cell1, Cell2, and Cell3 each corresponding to an integrator and Cell4 being an adder and quantizer stage.

Given that sigma-delta modulator topologies for CIFF converters are well known, constraints determined by these converter hardware topologies have already been applied to the generic encoder model 200 in the form of a binary mask to mask the weights, that is, the data paths, absent from these known hardware topologies. Further, based on this prior knowledge of the targeted topology, D is set to be equal to 2.

Thus, after masking, the matrix WM of weights of the example of the generic encoder model to match a known CIFF topology can be written as:

$${WM}^{T} = ( \begin{matrix}W 1 x & 0 & 0 & W 4 x \\ 0 & 0 & 0 & 0 \\ 0 & 0 & 0 & W a 410 \\ 0 & 0 & 0 & 0 \\ Wa 111 & W a 211 & 0 & 0 \\ 0 & 0 & 0 & 0 \\ 0 & 0 & 0 & W a 420 \\ 0 & 0 & 0 & 0 \\ 0 & W a 221 & W a 321 & 0 \\ 0 & 0 & 0 & 0 \\ 0 & 0 & 0 & W a 430 \\ 0 & 0 & 0 & 0 \\ 0 & 0 & W a 331 & 0 \\ 0 & 0 & 0 & 0 \\ 0 & 0 & 0 & 0 \\ W b 141 & 0 & 0 & 0 \\ 0 & 0 & 0 & 0\end{matrix} ) \qquad [ Math 19 ]$$

The decoder (or filter) of the CIFF converter model used herein is of the type described in relation with FIG. 8.

The trained models are compared with a known 3rd-order CIFF converter, referred to hereafter as the reference CIFF converter and corresponding to the matrix in the above equation [Math 19] in which the non-zero weights have the following values:
W1x=0.5674;
Wa111=1.0000;
Wb141=−0.5674;
Wa211=0.5126;
Wa221=1.0000;
Wa321=0.3171;
Wa331=1.0000;
W4x=1.0000;
Wa410=1.4000;
Wa420=0.9900; and
Wa430=0.4700.

To compare reference converter CIFF with converters obtained by training of the model, that is, by training of matrix [Math 19], the maximum error over the entire dynamic range DR of the converter is observed. The metrics MAXresol defined by [Math 18] is also used.

Further, a maximum value N equal to 100 is here set.

Further, trainings of the model performed with random noise according to a Gaussian distribution having a standard deviation equal to 0.25*10−3 are compared, this random noise being added to the model, at the output of each cell Cellk, as a data augmentation layer.

To compare the performance of a converter obtained after a supervised deep learning with that of the reference converter, metric MAXresol is for example used, for example, with test signals having an equivalent dynamic range. In particular, the signals of the model have a maximum excursion corresponding, for example, to the range [−0.5; 0.5]. The input data used for the training have a dynamic range within the range [−0.4; 0.4] and the input data used for testing have a dynamic range within the range [−0.35; 0.35]. The dynamic range DR of the converter will be a resultant of the training. Thus, if the training is such that, at step 920 (FIG. 9), the trained model meets the targeted specifications, then the converter corresponding to the trained model will have a dynamic range DR at least adapted to the test data. As an example, for the reference converter, the dynamic range of the input data corresponds to the range [−0.35; 0.35].

Further, to assess the impact of the selection of function Fcost on the training, there are here considered a function Fcost1=Frmse+Fdr, a function Fcost2=Flse+Fdr, a function Fcost3=Fmix+Fdr, and a function Fcost4=Fmax+Fdr, with A and B respectively equal to 0.8 and 0.2 in fidelity function Fmix, and Δk equal to 0.4 in the expression of function Fdr according to [Math 15].

The value of metric MAXresol obtained by simulating the trained model in the absence of temporal noise, is:
better (higher) than that obtained for the reference converter when the model has been trained with function Fcost2 or Fcost3,
not as good (lower) as that obtained for the reference converter when the model has been trained with function Fcost1, and
better (higher) than that obtained for the reference converter when the model has been trained with function Fcost4 for values of N greater than 50.

The value of metric MAXresol obtained by simulation of the trained model in the presence of noise is:
better than that obtained for the reference converter when the model has been trained with function Fcost2 or Fcost3 for values of N smaller than 50, and
not as good as that obtained for the reference converter when the model has been trained with function Fcost1,
not as good as that obtained for the reference converter when the model has been trained with function Fcost4 for values of N smaller than 50,
similar to that obtained for the reference converter when the model has been trained with function Fcost4 for values of N greater than 50.

As an example, the matrix of the modulator weights obtained with a training using function Fcost2 and with the data augmentation layers introducing random temporal noise can be written as:

$${WM}^{T} = ( \begin{matrix}0.4922 & 0 & 0 & 0.7467 \\ 0 & 0 & 0 & 0 \\ 0 & 0 & 0 & 1.2985 \\ 0 & 0 & 0 & 0 \\ 1.0197 & 0.3713 & 0 & 0 \\ 0 & 0 & 0 & 0 \\ 0 & 0 & 0 & 1.0519 \\ 0 & 0 & 0 & 0 \\ 0 & 1.0192 & 0.1166 & 0 \\ 0 & 0 & 0 & 0 \\ 0 & 0 & 0 & 1.102 \\ 0 & 0 & 0 & 0 \\ 0 & 0 & 1.0195 & 0 \\ 0 & 0 & 0 & 0 \\ 0 & 0 & 0 & 0 \\ - 0.5014 & 0 & 0 & 0 \\ 0 & 0 & 0 & 0\end{matrix} ) \qquad [ Math 20 ]$$

As an example, the modulator corresponding to the trained model may be implemented as described with FIGS. 10 and 11 for an implementation of the weights in capacitive form, or as described in relation with FIGS. 12 to 16 for an implementation of the weights in resistive form.

Referring again to the example of the trained model obtained as indicated by [Math 20], the quantization error for this trained model has been compared with that of the reference converter, with and without temporal noise, for a value N equal to 100.

In the absence of temporal noise, it has been observed that this quantization error is lower for the trained model than for the reference converter for input signals x having a value xa in the range from −0.35 to approximately −0.30 and from approximately 0.30 to 0.35, that is, at the limits of dynamic range DR.

In the presence of temporal noise, quantization errors for the trained model and for the reference converter are similar all throughout dynamic range DR.

Another example of implementation of the method described in FIG. 9 will now be described.

In this other example, it is provided to train a model corresponding to the topology defined by the weight matrix of [Math 21]:

$${WM}^{T} = ( \begin{matrix}W 1 x & W 2 x & W 3 x & W 4 x \\ 0 & 0 & 0 & 0 \\ 0 & 0 & 0 & W a 410 \\ 0 & 0 & 0 & 0 \\ W a 111 & W a 211 & W a 311 & 0 \\ 0 & 0 & 0 & 0 \\ 0 & 0 & 0 & W a 420 \\ 0 & 0 & 0 & 0 \\ W a 121 & W a 221 & W a 321 & 0 \\ 0 & 0 & 0 & 0 \\ 0 & 0 & 0 & W a 430 \\ 0 & 0 & 0 & 0 \\ W a 131 & W a 231 & W a 331 & 0 \\ 0 & 0 & 0 & 0 \\ 0 & 0 & 0 & 0 \\ W b 141 & W b 241 & W b 341 & 0 \\ 0 & 0 & 0 & 0\end{matrix} ) \qquad [ Math 21 ]$$

In other words, this model comprises K equals 4 cells Cellk. Cell1, Cell2, Cell3, and Cell4 all receive signal x[n] and apply respective weights W1x, W2x, W3x, and W4x thereto. Cell1, Cell2, and Cell3 all receive the non-quantized output delayed by one cycle A11[n] from Cell1 and apply respective weights Wa111, Wa211, and Wa311 thereto. Cells Cell1, Cell2, and Cell3 all receive the non-quantized output delayed by one cycle A21[n] from cell Cell2 and apply respective weights Wa121, Wa221, and Wa321 thereto. Cell1, Cell2, and Cell3 all receive the non-quantized output delayed by one cycle A31[n] from Cell3 and apply respective weights Wa131, Wa231, and Wa331 thereto. Cell1, Cell2, and Cell3 all receive the quantized and delayed output B41[n] from Cell4 and apply respective weights Wb141, Wb241, and Wb341 thereto. Cell4 receives the non-quantized and non-delayed outputs A10[n], A20[n], and A30[n] from the respective cells Cell1, Cell2, and Cell3, and applies respective weights Wa410, Wa420, and Wa430 thereto. The other connections are absent, and their corresponding weights are zero, and these weights are kept zero during the training due to a constraint applied to the model, in practice a binary mask.

The model defined by [Math 21] is a mixed topology between a CIFF and a CIFB (Cascaded Integrators Feed-Backward) topology.

The value of metric MAXresol obtained by simulating the trained model in the absence of temporal noise, is:
better for the topology of matrix [Math 21] than for the topology of matrix [Math 20] for values of N greater than 50 when the models have been trained with function Fcost2 or Fcost3,
similar for the topology of matrix [Math 21] and for the topology of matrix [Math 20] for values of N smaller than 50 when the models have been trained with function Fcost2 or Fcost3, and
similar for the topology of matrix [Math 21] and for the topology of matrix [Math 20] for values of N in the range from 1 to 100 when the models have been trained with function Fcost4.

The value of metric MAXresol obtained by simulation of the trained model in the presence of temporal noise is:
better for the topology of matrix [Math 21] than for the topology of matrix [Math 20] for values of N greater than 50 when the models have been trained with function Fcost2 or Fcost3,
similar for the topology of matrix [Math 21] and for the topology of matrix [Math 20] for values of N smaller than 50 when the models have been trained with function Fcost2 or Fcost3, and
similar for the topology of matrix [Math 21] and for the topology of matrix [Math 20] for values of N in the range from 1 to 100 when the models have been trained with function Fcost4.

As an example, the trained model obtained with function Fcost2 from the topology of matrix [Math 21] corresponds to the following weight matrix:

$${WM}^{T} = ( \begin{matrix}0.4919 & 0.2338 & 0.281 & 0.1613 \\ 0 & 0 & 0 & 0 \\ 0 & 0 & 0 & 0.6285 \\ 0 & 0 & 0 & 0 \\ 1.0193 & 0.3723 & 0.1167 & 0 \\ 0 & 0 & 0 & 0.5667 \\ 0 & 0 & 0 & 0 \\ 0 & 0 & 0 & 0 \\ - 0.0003 & 1.0196 & 0.1557 & 0 \\ 0 & 0 & 0 & 0 \\ 0 & 0 & 0 & 0.8706 \\ 0 & 0 & 0 & 0 \\ - 0.0001 & - 0.0001 & 1.0006 & 0 \\ 0 & 0 & 0 & 0 \\ 0 & 0 & 0 & 0 \\ - 0.4938 & - 0.2278 & - 0.2373 & 0 \\ 0 & 0 & 0 & 0\end{matrix} ) \qquad [ Math 22 ]$$

For this example of a trained model, it has been observed that the quantization error of the trained model is better than that of the reference converter all throughout dynamic range DR when there is no temporal noise. Further, the INL (Integral Non Linearity) is better for the trained model.

Taking the example of trained model corresponding to [Math 22], or starting again from the model corresponding to the topology of matrix [Math 21], a new quantization-aware training step is implemented to obtain quantized weights.

In this example, in equation [Math 17], qstep is a value learned by using a learned weight W^{l}scale, and is then equal to 1/(round((2^{q-1})/W^{l}scale)). Further, a constraint is applied to the model so that the quantized weights are all multiples of a factor 1/s with s an integer.

A matrix WMq of quantized weights multiple of a unitary element (common denominator) of value 1/s with s equal to 6 is then obtained. Further, the learned value of qstep is equal to 4, and the quantized weight matrix can be written as:

$${WMq}^{T} = ( \begin{matrix}3 & 1 & 2 & 4 \\ 0 & 0 & 0 & 0 \\ 0 & 0 & 0 & 1 \\ 0 & 0 & 0 & 0 \\ 6 & 2 & 0 & 0 \\ 0 & 0 & 0 & 0 \\ 0 & 0 & 0 & 5 \\ 0 & 0 & 0 & 0 \\ 0 & 6 & 1 & 0 \\ 0 & 0 & 0 & 0 \\ 0 & 0 & 0 & 8 \\ 0 & 0 & 0 & 0 \\ 0 & 0 & 6 & 0 \\ 0 & 0 & 0 & 0 \\ 0 & 0 & 0 & 0 \\ - 3 & - 1 & - 2 & 0 \\ 0 & 0 & 0 & 0\end{matrix} ) \qquad [ Math 23 ]$$

Each non-zero weight is implemented by multiplying its quantized value by the value of the unitary element, in this example equal to 1/s with s equal to 6.

This implementation with quantized weights is compared with a reference converter corresponding to the reference converter of the previous examples, in which the weights have been quantized. It can then be observed that, in this reference converter with quantized weights, the output signals of the stages saturate, while this is not the case for the output signals of the cells Cellk of the trained model with quantized weights of [Math 23].

Further, the trained model with quantized weights of [Math 23] has a quantization error much lower than that of the reference converter with quantized weights, all throughout dynamic range DR, for a value N equal to 100.

This results from the fact that the conventional sizing methodology enabling to obtain the quantized weights of the reference converter from the non-quantized weights of this reference converter does not take into account the effects of weight quantization. Conversely, the method disclosed herein, enabling for example to obtain the quantized weight matrix [Math 23], takes these effects into account when the training is quantization-aware. This illustrates the advantage of a training jointly satisfying all the material specifications transcribed in the form of constraints or of regularizations, conversely to a standard sizing approach requiring a sequential adjustment of parameters of the topology.

As an example, as previously mentioned, it is possible to implement an L0 or L1 regularization during a quantization-aware training. It has been observed that, by increasing the weight of an L1 regularization (which aims at introducing a penalty depending on the sum of the absolute values of the latent weights of the encoder), the number of non-zero weights tends to decrease. Increasing the weight of the L1 regularization results in a more compact trained model, for example, a trained model corresponding to an order 2 rather than an order 3, as is the case with the trained model corresponding to the matrix [Math 23], but with a lower performance.

In the examples of analog-to-digital converter training described hereabove, preferably, the quantized outputs of the cells Cellk are not used, for example being masked by a masking matrix, except as concerns the last cell.

As another example, it is provided to keep, for each cell Cellk, at least one quantized output Bkd[n], and to deliver all these quantized outputs to a filter designed to process these bit streams.

Another example of implementation of the previously-described method of FIG. 9 will now be described.

In this other example, it is provided to train a converter model in which the filter receives at least one quantized output Bkd[n] from each cell Cellk.

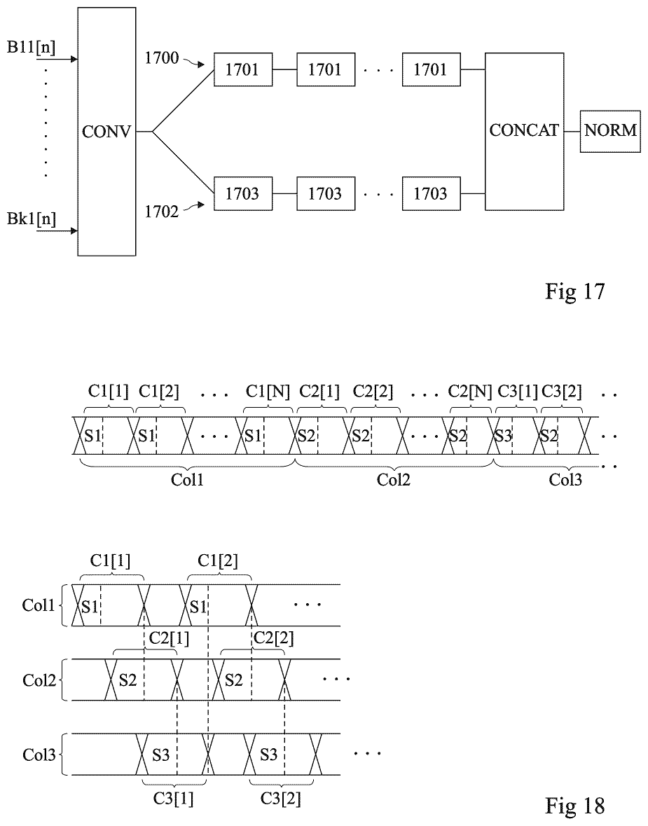

FIG. 17 shows an example of a filter model for processing bit streams originating from the K cells Cellk of a generic modulator model, in the case where each cell supplies a bit stream corresponding to the output Bk1[n] of the cell.

At each cycle C[n] of a conversion, the filter receives K bit streams Bk1[n].

The filter comprises a first one-dimensional convolutional layer CONV. This convolutional layer is configured to perform, at each cycle C[n], recombinations of the K streams Bk1 over a given time depth, to enrich the expressiveness of the filter.

For example, layer CONV receives K channels Bk1 having a time depth N. Layer CONV then performs C*K convolutions of depth v. For example, layer CONV calculates C values, each value being a weighted sum of K convolutions of depth v applied to the K received channels. Layer CONV then outputs a vector of dimension C, updated at each conversion cycle C[n].

The output of this convolutional layer CONV is supplied to a first branch 1700 of the filter. The first branch comprises a number of cascaded cells or neural networks SRNN (Simple Recurrent Neural Network), with no activation layer. In FIG. 17, each SRNN cell or network is designated with reference 1701. As an example, the first network 1701 is similar to the network SRNN1 of FIG. 8, with the difference that, rather than receiving a single bit Bk0[n] and than applying a single weight Wd1 thereto, this network receives a vector of C elements to which it applies a corresponding vector of C weights. Further, recurrent network SRNN1 further receives as inputs as many signals as it delivers outputs, each of these input signals being determined by a corresponding output of the network, and to which it applies a weight vector Wc1 having a size equal to the number of outputs of the network. In this example, the network provides a single output and vector Wc1 comprises a single weight. As an example, the number of networks 1701 is determined by the targeted filtering accuracy, and is, for example, greater than or equal to K.

The output of layer CONV is also supplied to a second branch 1702 of the filter. The second branch comprises cascaded gated recurrent units (GRUs), for example with a linear and sigmoid activation. Gated recurrent units are well known to those skilled in the art and are not defined again herein. In FIG. 17, each gated recurrent unit is designated with reference 1703. As an example, the number of recurrent units is the same as the number of networks 1701.

Each of branches 1700 and 1702 thus delivers a single data item (or signal) updated at each cycle C[n]. The outputs delivered by each of branches 1700 and 1702 are then concatenated, as illustrated in FIG. 17 by a block “CONCAT”.

The filter eventually comprises a layer NORM for normalizing the output of layer CONCAT, that is, a data vector of dimension 2, updated at each cycle C[n]. Layer NORM performs, at each cycle C[n], a weighted sum, with learned weights, of the two data items in the 2-dimensional vector that it receives.

In another example, branch 1702 and concatenation CONCAT may be omitted, as well as the convolutional block, to only keep branch 1700, which will directly receive as inputs the K streams Bk1.

As an example, there is considered a generic model in which:
for the modulator:
   K is equal to 4;
   the maximum value of N is 100;
   the ranges of value of the training input data, of the simulation input data, and of the inner signals of the modulator are the same as those defined for the previous examples;
   m=4;
   data augmentation layers adding Gaussian random noise with a standard deviation equal to 0.25*10−3 are added at the output of each of the K cells Cellk;
   a weight masking matrix is applied to the weights matrix WM of the modulator, to mask:
   for each cell Cellk but the last one, weights Wak40, Wbk40, Wak41, and
   for the last cell Cell4, weights other than W4x, Wa410, Wb410, Wa420, Wb420, Wa430, and Wb430; and
for the filter:
   the convolution is only performed on the delayed quantized outputs of the K cells Cellk, that is, on the outputs Bk1[n] of the K cells Cellk;
   branch 1700 comprises 4 networks 1701; and
   branch 1702 comprises 4 units 1703.

Preferably, to facilitate the convergence during the training of the model from a plurality of sets of input data xa, a normalization layer is added to the model, at the output of the filter, which is configured, for each set of training data xa, to apply a corrective gain aligning the average of the absolute values of the signals xq obtained for this set of data xa, with the mean of the absolute values of the input data xa of this set. In this case, a statistical property is imposed on the training data, which consists in that, in each data set xa used, the data xa follow a distribution with a known and identical mean of the absolute values for all sets. Such a statistical property corresponds to a learning strategy such as illustrated by block 919 (“STAT”) in FIG. 9.

Preferably, to facilitate the convergence during the learning of the model, data regularization layers are added at the output of each cell Cellk, to introduce, for each set of input data xa, a penalty proportional to the difference between the mean of the absolute values targeted for this set and the mean of the absolute values obtained for this set at the output of each cell Cellk. In this case, the same statistical property as hereabove is imposed on the training data sets.

Preferably, to facilitate the convergence during the learning of the model, the learning rate is made dependent on the current value of metric MAXresol, in addition to a conventional decrease in the learning rate based on the epoch rank. This corresponds to a learning strategy illustrated by block 918 (“CB FCT”) in FIG. 9.

Preferably, to facilitate the convergence during the learning of the model, two different learning rates are provided, one for the filter, the other for the modulator, and, at each epoch, only one of the two learning rates is updated by a callback function, alternating one epoch with an update of the first rate and one epoch with an update of the second rate. This corresponds to a learning strategy illustrated by block 918 (“CB FCT”) in FIG. 9. The advantage of providing these two learning rates is to alternate, along epochs, that of the two learning rates which is the strongest, for example ten times stronger than the other learning rate for the considered epoch, so as to stabilize the learning, while not freezing the updating of weights.

Preferably, the training is quantization-aware, but with a quantization step qstep which is no longer based on the maximum value of the absolute values at latent weights and equal to 1/(round((2^{q-1})/W^{l}max)), but which is learned during the training and equal to 1/(round((2^{q-1})/W^{l}scale)), with W^{l}scale a weight learned during the training.

In the considered example, the cost function used is function Fcost2.

The trained model with quantized weights obtained for this example then has a lower quantization error than that of the trained model with quantized weights corresponding to [Math 23], and is also more robust to noise. Thus, this example shows that the use, by the filter, of the quantized outputs of each cell Cellk enables to improve the analog-to-digital conversion.

Another example of implementation of the method of FIG. 9 will now be described.

In this other example, the case where the converter to be manufactured is configured to implement analog-to-digital conversions at the foot of a column of a pixel matrix within an image sensor is here considered. It is conventionally provided to place one converter per column, so that on reading of a line, each converter converts the output signal of a pixel of its column. However, this results in a cumbersome implementation due to the surface area occupied by each converter.

Reading a plurality of columns with a single converter enables to release implementation constraints, in particular constraints relating to the surface area available at the foot of each column. In such an implementation, a single converter is provided for a plurality of columns, for example three columns, which enables to divide by 3 the number of converters. In this case, the converter first converts the signal from a first column in the set over N cycles, then the signal from a second column in the set over N cycles, and so on until all columns have been read. However, the time required for each cycle is limited by the time required to sample the signal, whereby the time required for a converter to read all the columns with which it is associated is limited. Indeed, in a capacitive converter, at each of the N conversion cycles, an input capacitive element of the converter must first be charged with the output signal of the column corresponding to the signal to be converted. Now, this charging time is generally long, for example, due to the properties of the source-follower transistor of the pixel which is responsible for the charging of the capacitive element.

Thus, in this example of application, there is provided a converter implementing a reading method, more particularly a sampling method, in which the columns associated with a same converter are sampled by this converter one after the other, cyclically and repeatedly, at the converter input. In other words, there is provided a converter in which channels at the converter input are sampled in cyclically, alternated, and interleaved fashion. Thereby, while the converter is sampling one column, it can process the sample available for the previous column. This enables to decrease the total time required to convert the output signals of all the columns associated with the converter.

FIG. 18 illustrates the case of a converter associated with three columns Col1, Col2, and Col3, that is, a multiplexing of three columns to one converter, in the case where the columns are read sequentially, one after the other (at the top of FIG. 18), and in the case where the reading of the columns is performed in cyclic and interleaved fashion (at the bottom of FIG. 18). More specifically, during the interleaved reading of the columns, the N conversion cycles of each column are interleaved cyclically with the N conversion cycles of each of the other columns.

In FIG. 18, at the top, column Col1 is first read by the converter. This reading corresponds to N cycles C[n], designated with reference C1[n] in FIG. 18, each cycle C1[n] starting with a period S1 corresponding to the sampling of the output signal of column Col1. Then, column Col2 is read in a second step by the same converter. This second reading corresponds to N cycles C[n], designated with reference C2[n] in FIG. 18, each cycle C2[n] starting with a period S2 corresponding to the sampling of the output signal of column Col2. Finally, column Col3 is read last by the converter. This last reading corresponds to N cycles C[n], designated with reference C3[n] in FIG. 18, each cycle C3[n] starting with a period S3 corresponding to the sampling of the output signal of column Col3.

In FIG. 18, at the bottom, the N readout cycles of each column are interleaved in cyclic and overlapping fashion with the N readout cycles of each other column. For example, the converter successively implements a cycle C1[n], then a cycle C2[n], then a cycle C3[n], and repeats this pattern N times. During each cycle C1[n], the period S2 of cycle C2[n] is implemented so that, as soon as cycle C1[n] ends, period S2 is over. During each cycle C2[n], the period S3 of cycle C3[n] is implemented so that, as soon as cycle C2[n] ends, period S3 is over. Finally, during each cycle C3[n], the period S3 of cycle C1[n+1] is implemented so that, as soon as cycle C3[n] ends, S3 period is over.

As a result, the total time required by the converter to read the 3 columns is shorter in the case where the N conversion cycles of each column are interleaved in cyclic and overlapping fashion with the N conversion cycles of each other column, than in the case where the N reading cycles of each column are implemented successively for each column and the columns are read one after the other, without decreasing the S1, S2, S3 sampling times of the output values of columns Col1, Col2, Col3. This results from the fact that, when the N conversion cycles of each column are interleaved in cyclic and overlapping fashion with the N conversion cycles of each other column in a pattern repeated N times, the sampling of the conversion cycle corresponding to the column is implemented during the previous conversion cycle corresponding to another column.

To implement the above-described operation, there is provided, in the hardware implementation of the converter to be manufactured, a sampling circuit TSample with T inputs and one output, where T is the number of columns associated with the converter. The sampling circuit is configured to cyclically and periodically sample the T columns one after the other. In addition, each time the output of the sampling circuit provides a sampled signal corresponding to a column, the sampling circuit implements the sampling of another column. Thus, while the converter encoder is receiving and processing the sampled signal available at the output of the sampling circuit and corresponding to one of the T columns, the sampling circuit is sampling another of the T columns. In an implementation based on sampling capacitive elements, unlike the solution shown at the top of FIG. 18 in which a single sampling capacitive element is available at the converter input, the provided interleaved solution however implies the presence of T sampling capacitive elements in order to manage overlaps.

The conversion of the output signals of T columns, when a conversion is carried out in N cycles, is carried out in T*N cycles C[n], with n an index ranging from 1 to T*N. In each cycle C[n], the quantized outputs Bkd of each cell Cellk are stored for each update of the input vector of one of the K converter cells, the update of each cell being performed, for example, from left to right and the set of stored outputs is supplied to the decoder at the end of cycle C[n] in the form of a corresponding vector Z[n]. In other words, at each beginning of an intracycle of a cycle C[n], where an intracycle starts when a cell Cellk supplies its updated outputs to the next cell Cellk, all the outputs Bkd of the K cells Cellk are stored, and all these stored values are supplied at the end of cycle C[n] in the form of a vector Z[n] to the decoder. Thus, this vector Z[n] comprises D*K Bkd signals for each intracycle, that is, D*K*K Bkd signals at the end of cycle C[n]. It is important to note that this notion of intracycle enables to use the transient variation of the outputs Bk0d of a given cycle C[n]. In the case where only outputs Bk1d are taken into account, the notion of intracycle is meaningless, since all cells are updated at the same time.

The decoder model used comprises, for example, T branches 1900, each comprising a plurality of simple recurrent neural networks 1902. The first simple recurrent neural network 1902 of each branch 1900 is configured to receive an input vector having the dimension of vector Z[n], and thus comprises a weight vector having the dimension of vector Z[n] plus one (for the signal for looping back the network on itself in the case of single-output simple recurrent networks). The following networks 1902 of the branch are, for example, similar to the networks SRNN2 and SRNN3 described in relation with FIG. 8.

The decoder further comprises a demultiplexing circuit Cmux. Circuit Cmux receives each of the T*N vectors Z[n]. Circuit Cmux is configured to supply the Z[n] vectors that it receives alternately and cyclically to each of the T branches 1900. Thus, for each cycle C[n] corresponding to one of the T columns, the vector Z[n] obtained at the end of cycle C[n] is supplied to the same branch of the T branches 1700 of the filter. Each branch 1900 of the decoder then provides the conversion result of a corresponding column.

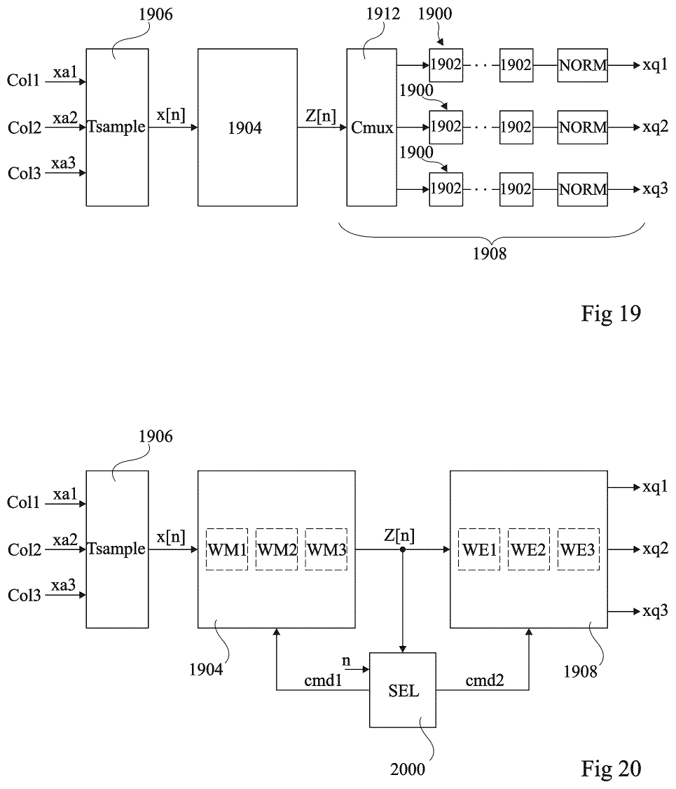

FIG. 19 shows an example of a converter model such as described hereabove, in the case where T is equal to 3.

Encoder 1904 comprises K equals 4 cells Cellk in this example, and is shown in the form of a block so as not to overload the drawing. The converter model comprises a block 1906 (block “TSample” in FIG. 19) implementing, in the model, the function of the sampling circuit TSample which will form part of the converter once manufactured. Block Tsample receives the output signals xa1, xa2, and xa3 of the T columns Col1, Col2, and Col3. The output vector Z[n] of the encoder, that is, the vector Z[n] available at the end of each of the T*N cycles C[n], is supplied by encoder 1904 to the filter, or decoder, 1908.

Filter 1908 comprises the T=3 branches 1900 of cascaded networks 1902. As an example, each branch comprises K=4 cascaded networks 1902. Optionally, each branch 1900 comprises a 1910 normalization layer (block “NORM” in FIG. 19) connected to the last network 1902 in the branch. Decoder 1908 comprises a block 1912 (block “Cmux” in FIG. 19) implementing, in the model, the function of circuit Cmux which will form part of the converter once manufactured.

Each branch delivers a digital signal corresponding to the conversion of the signal of one of the T columns. For example, a first branch 1900 delivers a signal xq1 corresponding to the conversion of signal xa1, a second branch delivers a signal xq2 corresponding to the conversion of signal xa2, and a third branch delivers a signal xq3 corresponding to the conversion of signal xa1.

As an example, by training a converter model of the type of that in FIG. 19 in which: the modulator comprises K equals four cells Cellk,
N equals T*40,
T equals 3,
D equals 2,
data augmentation layers are provided and introduce Gaussian random noise with a standard deviation equal to 0.25*10−3,
the ranges of values of the training input data, the simulation input data, and the inner signals of the modulator are the same as those defined for the previous examples,
the demodulator corresponds to the decoder 1908 described in relation with FIG. 19,
and in which the training is implemented as follows:
the training is quantization-aware, with q in the range from 10 to 20,
the cost function used is function Fcost2,
the inventors have obtained a trained converter model operating with the multiplexing on its input described hereabove with T equal to 3, with a unitary weight for the quantized weights equal to 1.18889*10−6 for q equal to 20.

For each column, the performance of conversion by the trained converter, for example assessed with metric MAXresol, is similar to that obtained by providing one independent converter per column implementing a conversion over N cycles.

This example of training an analog-to-digital converter demonstrates the value of the generic encoder model provided herein, as well as of the provided converter design method. In particular, this example shows that it is possible to train the generic encoder model jointly with a filter model in the form of neural networks, or, in other words, a filter modeled by neural networks, so as to implement an analog-to-information conversion function. Without the method provided herein, and in particular without the generic encoder model provided herein, there exists no method enabling to determine and size a converter topology enabling to implement the same multiplexing/demultiplexing between a plurality of channels, where the sampling is cyclically and periodically alternated between channels.

Another example of implementation of the previously-described method of FIG. 9 will now be described.

In this other example, the converter to be manufactured is of the type described in the previous example, that is, with an alternating, cyclic, and periodic multiplexing of T channels to be converted at the input of the converter encoder, and an alternating, cyclic, and periodic demultiplexing of output vector Z[n] from the encoder to T branches of the decoder, the multiplexing and the demultiplexing being updated at each beginning of the T*N conversion cycles C[n]. However, it is here also provided to provide R weight matrices WMi for the encoder model, with i ranging from 1 to R, and, optionally, V weight matrices WEj for the decoder, with j ranging from 1 to V. In this example, R and V are equal to T. An additional function SEL is added to the converter model. This function is configured to select which of matrices WMi, and, when the optional matrices WEj are provided, which of matrices WEj, are to be used at each of the T*N Cycles C[n], based on the analysis of a plurality of vectors Z[n] delivered by the encoder during the previous cycles C[n] and on the knowledge of the index n of the current cycle C[n]. This function SEL, corresponding to an attention mechanism, is, for example, added to the model in the form of a neural network. Preferably, during the training, a regularization is applied to the weights of matrices WMi to force these different weight matrices WMi to have a given weight ratio in common. Indeed, this enables to have a more compact hardware implementation. A similar regularization may be provided for the different weight matrices WEj.

An example of such a converter model is illustrated, very schematically and functionally in FIG. 20, in the case where R and V are equal to 3, and where T is equal to 3.

As can be seen in FIG. 20, encoder model 1904 comprises the R=3 weight matrices WM1, WM2, and WM3, and, in this example, decoder model 1908 comprises the V=3 weight matrices WE1, WE2, and WE3. A block 2000 (“SEL” in FIG. 20) receives the output vectors Z[n] from encoder 1904, and the index n of the current cycle C[n]. This block 2000 then determines, based on a plurality of vectors Z[n] received during the cycles C[n] preceding the current cycle C[n], which of weight matrices WM1, WM2, and WM3 is to be used at encoder 1904 for the current cycle C[n], and, when V matrices WEj are provided for the decoder, which of weight matrices WE1, WE2, and WE3 is to be used at the decoder for this current cycle C[n]. Function SEL indicates to encoder 1904 the matrix WMi selected for the current cycle, and to decoder 1908 the matrix WEj selected for this current cycle, via two respective signals cmd1 and cmd2.

To implement in hardware fashion the model of FIG. 20, after having trained it, each weight in common between the three matrices WM1, WM2, WM3 may be implemented by a single corresponding circuit, for example a single circuit Cpos or Cneg, and when a weight is different according to the considered matrix WM1, WM2, WM3, each different value of this weight is implemented by a corresponding dedicated circuit, and this circuit is selected (or enabled or connected in a corresponding data path) when the matrix WMi to which it belongs is selected by circuit 2000, and deselected (or disabled or disconnected from the corresponding data path) when another matrix WMi is selected by circuit 2000. As an example, circuit 2000 may be implemented by a digital circuit adapted to implementing the trained neural network corresponding to function SEL. As an example, a regularization function may be used to favor a limited difference between the R matrices WMi.

In a non-illustrated alternative embodiment, only the R matrices WMi of encoder 1904 and function SEL are provided, decoder 1908 being modeled by a single weight matrix, identical for all conversion cycles.

In another example, not illustrated, of the implementation of the previously-described method of FIG. 9, it is provided to modify the matrix WM of encoders weight and that WE of decoder weights as a function of the current index n of the conversion, similarly to what is described in patent application EP 3259847.

Thus, two pairs WM1, WE1 and WM2, WE2 of encoder and decoder weight matrices are provided.

A value of the index n of the cycle C[n] at which the pair of matrices WM1, WE1 is replaced by the pair of matrices WM2, WE2 is learned during the supervised deep learning. For example, using a converter topology of the type defined by [Math 19], a constraint is applied to matrices WM1 and WM2 so that the weights of matrix WM1 corresponding to the non-quantized loopback paths delayed by one cycle of cells Cellk are forced to 1, that is, so that the weights Wall1, Wa221, and Wa331 are forced to 1 in the example of matrix [Math 19], and that these same weights are forced to a value greater than 1 in matrix WM2. Further, preferably, a regularization or a constraint is applied to the other weights of these two matrices WM1 and WM2 so that they are the same in both matrices, in order to decrease the complexity and the surface area of the converter which will be manufactured from the trained model.

Another example of implementation of the previously-described method of FIG. 9 will now be described.

In this other example, the converter to be manufactured is no longer intended to convert analog signals into digital signals, but is intended to extract one or a plurality of latent parameters from an analog input signal. In other words, in this example, the converter to be manufactured is an analog-to-information converter, and not an analog-to-digital converter said to be standard, in the sense that this converter is no longer limited to a static input signal and/or this converter no longer provides the digitized image of the input signal.

This example will be described in the case of a sinusoidal analog input signal xa, from which latent parameters are desired to be extracted.

More specifically, the sampled signal xa is expressed in the form x[n]=0.5*(A*sin(2*Π*F*n+φ)+C), with n ranging from 1 to N. The latent parameters to be extracted are, in this example:
the amplitude A uniformly distributed over an interval [−0.4; 0.4] for the training and [−0.35; 0.35] for simulations during tests;
frequency F expressed as follows:

$$F = \frac{1}{H * ( N - P min ) + ( \frac{P min + P max}{2} )} \qquad [ Math 24 ]$$

with H a parameter uniformly distributed over an interval [−0.45; 0.45] for the training and [−0.43; 0.43] for simulations during tests, Pmin for example equal to 4, and Pmax for example equal to N;
the DC component C uniformly distributed over an interval [−0.4; 0.4] for the training and [−0.35; 0.35] for simulations during tests; and
phase φ expressed as follows:

$$φ = arccos ( 2 X ) \qquad [ Math 25 ]$$

with X a parameter uniformly distributed over an interval [−0.45; 0.45] for the training and [−0.43; 0.43] for simulations during tests.

The converter model comprises J encoders ENCj, each comprising K cells Cellk, that is, J encoders such as those previously described, J being an integer greater than 1 and j being an index ranging from 1 to J. Each of the J encoders receives as an input, at each cycle C[n], a corresponding analog sample x[n].

At each cycle C[n], each encoder delivers a vector Zj[n] comprising the outputs Bk1 of each of the K cells Cellk of this encoder, these vectors Zj[n] being concatenated to form a vector V[n] comprising J*K elements.

The converter model comprises a decoder or filter receiving the vectors V[n] from the encoder formed of the J encoders of K cells Cellk.

The decoder comprises E convolutional layers CONVe, with E an integer equal to the number of latent parameters sought, and e an integer ranging from 1 to E. At each cycle C[n], each layer CONVe performs O convolutions over the last 1 successive vectors V[n] received, for example over 1=4 vectors V[n], with O a non-zero integer. In other words, each layer CONVe performs O convolutions on the time axis of the vectors V[n] with a depth of 1 cycles C[n]. Of course, those skilled in the art will have understood that each layer CONVe is then adapted to storing 1-1 successive vectors V[n], so as to be able to implement each of the O convolutions on 1 successive vectors V[n]. At each cycle C[n], each layer CONVe delivers a vector Ve[n] comprising the result of the O convolutions performed by layer CONVe at this cycle. These O convolutions are performed from O learned convolution kernels, independent of each other within the same layer and between E layers.

The decoder further comprises E filters FILTERe. Each filter FILTERe receives vector Ve[n] from a corresponding layer CONVe.

As an example, each filter FILTERe comprises a cascade of simple recurrent neural networks, that is, simple recurrent neural networks connected one after the other, preferably ending with a normalization layer (or stage).

For example, each filter FILTERe comprises at least four, for example five, simple recurrent neural networks.

Preferably, in each filter FILTERe, a stage introducing non-linearities is interposed between the output of the third simple recurrent neural network and the input of the fourth simple recurrent neural network. The purpose of this non-linearity is to facilitate the estimating of the spectral content of the signal in each band, independently of the signal power, so as to facilitate the extraction of parameter F. For example, the non-linearity stage is configured to calculate the square of each output value of the third simple recurrent neural network, to apply a normalization L2 to the squared values thus calculated (for example by dividing the sum of the squared values of the training batch), and to calculate the square root of these normalized values.

Each filter FILTERe is configured to deliver one of the desired latent parameters.

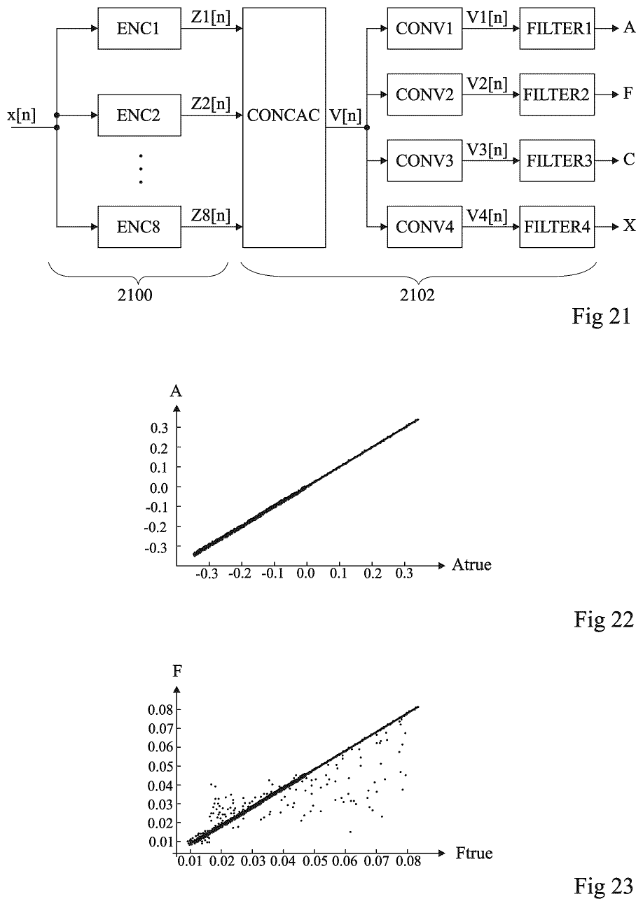

FIG. 21 schematically illustrates in the form of blocks an example of such a converter model, in the case where J is equal to 8 and E is equal to 4.

In this example, the converter model thus comprises:
a modulator 2100 comprising J encoders ENCj (ENC1, ENC2, . . . , ENC8 in FIG. 21); and
a filter 2102 comprising:
   a block CONCAT configured to implement the concatenation of J vectors Z[n] to deliver vector V[n],
   E convolutional layers CONVe (CONV1, CONV2, CONV3, CONV4 in FIG. 21), each implementing O convolutions with a depth for example equal to 4 on the time axis, and
   E filters FILTERe (FILTER1, FILTER2, FILTER3, FILTER4 in FIG. 21).

At each cycle C[n]:
each of the J encoders ENC1, ENC2, . . . , ENC8 receives the sampled analog signal x[n], and delivers a corresponding vector respectively Z1[n], Z2[n], . . . , Z8[n],
block CONCAT delivers the vector V[n] based on the J vectors Zi[n],
each of layers CONV1, CONV2, CONV3, CONV4 receives vector V[n], performs O convolutions on this vector and the previous 1-1 vectors, and delivers the respective vector V1[n], V2[n], V3[n], and V4[n] comprising the result of the O convolutions;
each of filters FILTER1, FILTER2, FILTER3, and FILTER4 receives vector V1[n], V2[n], V3[n], and V4[n] respectively; and
at the Nth cycle C[n], that is, at the end of the conversion, the output of filter FILTER1 delivers the amplitude A of the input signal of the converter, the output of filter FILTER2 delivers the frequency F of the input signal of the converter, the output of filter FILTER3 delivers the DC component C of the input signal of the converter, and the output of filter FILTER4 delivers the value of parameter X from which the phase φ of the converter input signal can be calculated.

The model provided in FIG. 21 has been trained with:
a quantization-aware training,
N equal to 120,
a learning strategy consisting of learning the quantization step in the first encoder ENC1 only, and of applying the same learned quantization step to the other encoders of modulator 1200, which enables to limit the influence of variations of the capacitance values resulting from manufacturing variations in the converter to be manufactured, and to simplify the implementation of the weights by having a unitary capacitance value common to all encoders ENCj,
the use of the cost function Fcost2 adapted to the present case, and
the addition of layers introducing temporal noise on the output of each cell Cellk of each encoder ENCj.

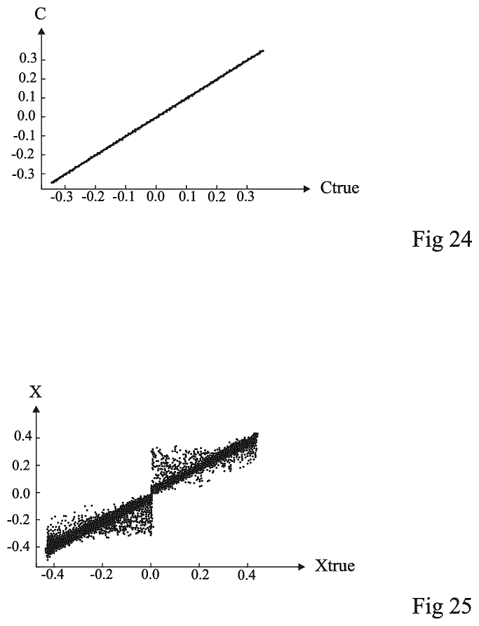

FIGS. 22, 23, 24, and 25 illustrate the variation of the values delivered by the trained converter for the respective parameters A, F, C, and X (axes of ordinates) as a function of the respective expected values Atrue, Ftrue, Ctrue, and Xtrue (axes of abscissas) of these parameters.

It should be noted that the conversion accuracy could be increased by increasing the value of parameter J and/or the depth of the convolutions E*O on the time axis and/or the number of cascaded simple recurrent neural networks in each filter FILTERe.

The above example shows that it is possible, starting from the generic encoder model based on K cells Cellk, to build an encoder model and to train it by supervised deep learning, so as to implement a given analog-to-information conversion. This converter may then be manufactured, for example by implementing each encoder of the trained converter model as described in relation with FIGS. 10 and 11 or 12 to 16, and by implementing the trained model of the decoder filter in software and/or hardware fashion, for example at least partly with a digital circuit adapted to implementing a neural network.

The obtaining of such a converter would not be possible with conventional design methods.

As a variant, it could be provided for each cell Cellk of encoder ENCj to have access to the outputs of the cells of another encoder. This would amount to increasing the size of the weight vector associated with the input of each cell Cellk, so as to be able to receive the output Akd or Bkd of at least one cell of another encoder. Regularization functions or constraints would, for example, be applied to avoid having too many non-zero weights. The exchange of data between a plurality of cells would enable to enrich the general expressiveness of the network. In this proposed variant, for example, the update of the outputs of cells Cellk may for example be performed from left to right within each encoder. As a summary, there would be groups of cells forming an encoder that can exchange signals with other groups of cells forming another encoder, with an update order for outputs Ak0 and Bk0 common between the different encoders or specific to each encoder.

Although an example of an analog-to-information converter has been described herein, other examples of analog-to-information converters can be designed due to the provided generic encoder model and to the provided design method. In particular, those skilled in the art will be capable of adapting the modeling of the filter in the form of neural networks to the desired functionality of the converter that they are designing.

Various embodiments and variants have been described. Those skilled in the art will understand that certain features of these various embodiments and variants may be combined, and other variants will occur to those skilled in the art.

In particular, the examples of regularizations, of constraints, and of learning strategies are not limited to those previously described as an illustration. Those skilled in the art will be capable of providing other constraints, for example determined by the material and/or functional properties of the converter to be manufactured, other regularizations, for example determined by the material and/or functional properties of the converter to be manufactured, and other learning strategies, for example determined by the material and/or functional properties of the converter to be manufactured. For example, those skilled in the art may rely on at least one of the following techniques enabling to explore network topologies with different learning or training strategies:
knowledge distillation: consists in training a neural network to behave like another neural network, which, when applied to the present disclosure, amounts to training a converter to behave like another converter;
Noise2Noise: consists in training a network to convert a noisy signal by calculating the cost function not from the output data of the network, but from noisy data obtained from output data to which noise has been added (for example with data augmentation layers at the network output);
contrastive learning: close input data (or data having a particular relationship at the input of the network) lead to close output data (or data having a particular relationship at the output of the network);
neural architecture search (NAS): consists in an automatic architecture search by progressively complexifying an initial simple topology.

Further, those skilled in the art will be capable of providing other functionalities for a converter to be manufactured than those which have described as an example, and will be capable of adapting the filter model to be connected after the generic encoder model as a function of these targeted functionalities, that is, for example, of adapting the modeling of the filter in the form of neural networks according to the targeted functionality in the converter to be manufactured.

Further, the example of values given as an example, for example for parameters Δk, λ, for the standard deviation of the Gaussian noise of the data augmentation layers, parameter K, parameter D, parameter N, parameter q, etc., may be modified by those skilled in the art, for example based on material and/or functional properties of the converter that they intend to design with the provided generic model and method, for example by implementing the described method a plurality of times and successively, and by modifying certain parameters at each new implementation, according to the converter that they intend to design.

Finally, the practical implementation of the described embodiments and variants is within the abilities of those skilled in the art based on the functional indications given hereabove. In particular, although this has not been described, the models of filters (that is, of decoder), once trained, can be implemented by digital circuits and/or computer programs adapted to implementing neural networks. Indeed, the data received by the described filters are quantized data easily representable by digital data that can be processed by software and/or by a digital circuit.

1. Method for designing a sigma-delta converter comprising a step of supervised deep learning applied to a converter model, wherein:
the converter model comprises at least one recurrent encoder and at least one recurrent decoder;
each recurrent encoder is based on a generic model comprising a succession of K identical generic cells Cellk, with K an integer parameter greater than or equal to 1 and k an integer index ranging from 1 to K;
the converter operates at an oversampling rate N, with N an integer greater than or equal to 1;
each conversion by the converter comprises N Cycles C[n], where n is an integer index ranging from 1 to N;
each cell Cellk of the generic model is a recurrent neural network which, at each cycle C[n], calculates a product of an input vector X[n] by a weight vector Wk of the cell Cellk and delivers an output vector Qk[n] comprising D pairs of outputs Akd[n] and Bkd[n], with:
D an integer greater than or equal to 1 and d an integer index ranging from 0 to D−1,
Akd[n] the result of the product calculated by the cell Cellk delayed by d cycles,
Bkd[n] a quantization of the result of the product calculated by the cell Cellk delayed by d cycles; and
at each beginning of a cycle C[n], vector X[n] is the same for all cells Cellk and comprises, for example is equal to, the concatenation of the K vectors Qk[n] and of a sample x[n], for cycle C[n], of a signal x to be converted,
and wherein the sigma-delta converter is obtained by manufacturing an electronic circuit corresponding to the model obtained after the training.

2. Method according to claim 1, wherein each recurrent encoder models a sigma-delta modulator of the converter and each recurrent decoder models a filter of the converter.

3. Method according to claim 1, wherein each recurrent decoder is based on one or a plurality of successions of simple recurrent neural networks.

4. Method according to claim 1, wherein at least one constraint determined by a material property or by a functional property of the converter to be manufactured is applied to the converter model, preferably to each encoder.

5. Method according to claim 4, wherein said at least one constraint comprises:
a constraint determined by a maximum dynamic range at the output of one of the K cells Cellk and corresponding to an addition of a clipping layer at the output of said cell Cellk; and/or
a constraint determined by robustness to temporal non-idealities and corresponding to an addition on an inner node of the encoder of a data augmentation layer modeling Gaussian random noise; and/or
a constraint determined by a sizing of circuits implementing weights of the encoder and corresponding to a quantization-aware training; and/or
a constraint determined by a surface area of the converter to be manufactured and corresponding to a masking of encoder weights; and/or
a constraint determined by a topology of the converter to be manufactured and corresponding to a masking of encoder weights; and/or
a constraint determined by a surface area of the converter and corresponding to a technique of clipping of weights of the encoder.

6. Method according to claim 1, wherein at least one regularization determined by a material property or by a functional property of the converter is applied to the converter model.

7. Method according to claim 6, wherein:
a regularization is determined by a surface area of the converter to be manufactured and corresponds to an L1 regularization applied to the encoder weights; and/or
a regularization is determined by an attenuation of inner signals and corresponds to a penalty when a weight of a loopback path of a cell Cellk is smaller than 1.

8. Method according to claim 1, wherein a cost function used for the training comprises a term determined by a regularization function determined by converter saturation conditions.

9. Method according to claim 7, wherein the cost function comprises a term determined by a fidelity function of the type of a logarithm of the sum of the exponentials of the differences.

10. Method according to claim 1, wherein the manufacturing of the converter comprises an implementation of each non-zero weight of the encoder model trained by a capacitive circuit having a capacitance, a value of which is determined by said weight.

11. Method according to claim 1, wherein the manufacturing of the converter comprises an implementation of each non-zero weight of the encoder model trained by a resistive circuit having a resistance, a value of which is determined by said weight.

12. Method according to claim 1, wherein the training is quantization-aware.

13. Method according to claim 1, wherein the decoder is determined by a functionality of the converter to be manufactured.

14. Method according to claim 1, wherein the converter to be manufactured implements a cyclic and alternated sampling of a plurality of input channels of the converter.
